(19) United States
(12) Patent Application Publication
(10) Pub. No.: US 2026/0179661 A1
(43) Pub. Date: Jun. 25, 2026

(54) MEMORY DEVICE

(71) Applicant: Kioxia Corporation, Tokyo (JP)

(72) Inventor: Toshiki MIYATANI, Yokohama (JP)

(73) Assignee: Kioxia Corporation, Tokyo (JP)

(21) Appl. No.: 19/319,882

(22) Filed: Sep. 5, 2025

(30) Foreign Application Priority Data
Dec. 19, 2024 (JP) 2024-223746

(51) Int. Cl. G11C 5/06; H10B 63/00; H10N 70/00

(52) U.S. Cl. CPC G11C 5/063; H10B 63/20; H10N 70/8822; H10N 70/8825; H10N 70/8828; H10N 70/8833

(57) ABSTRACT

A memory device of embodiments includes a memory cell including a first conductive layer, a switching layer, a third conductive layer, a variable resistance layer, and a second conductive layer in this order. The switching layer contains an oxide, a nitride, or an oxynitride of a first element selected from Al, Si, Ge, Zr, Y, Ta, La, Ce, Ti, Hf, and Mg, a second element different from the first element and selected from Al, Zn, Sn, Ga, and In, and a third element selected from Te, S, Se, and Sb. The switching layer includes a first region and a second region, and the sum of an atomic concentration of the second element and an atomic concentration of the third element in the first region is larger than a sum of an atomic concentration of the second element and an atomic concentration of the third element in the second region.

### CROSS-REFERENCE TO RELATED APPLICATION

This application is based upon and claims the benefit of priority from Japanese Patent Application No. 2024-223746, filed on Dec. 19, 2024, the entire contents of which are incorporated herein by reference.

### FIELD

Embodiments described herein relate generally to a memory device.

### BACKGROUND

As a large-capacity nonvolatile memory device, there is a cross-point type two-terminal memory device. In the cross-point type two-terminal memory device, scaling-down and high integration of memory cells are easy.

Each memory cell in the cross-point type two-terminal memory device has, for example, a variable resistance element and a switching element. Since the memory cell has a switching element, the current flowing through memory cells other than the selected memory cell is suppressed.

The switching element is required to have excellent characteristics, such as low leakage current, high on-current, and high reliability.

### BRIEF DESCRIPTION OF THE DRAWINGS

FIG. 1 is a block diagram of a memory device according to a first embodiment;

FIG. 2 is a schematic cross-sectional view of a memory cell in the memory device according to the first embodiment;

FIG. 3 is a diagram showing the distribution of the normalized additive concentration of a switching layer in the first embodiment;

FIG. 4 is an explanatory diagram of a problem of the memory device according to the first embodiment;

FIG. 5 is an explanatory diagram of the current-voltage characteristics of a switching element in the first embodiment;

FIG. 6 is a schematic cross-sectional view of a memory cell in a memory device according to a comparative example;

FIG. 7 is a graph showing the distribution of the normalized additive concentration of a switching layer in the comparative example;

FIG. 8 is a schematic cross-sectional view of a memory cell in a memory device according to a first modification example of the first embodiment;

FIG. 9 is a schematic cross-sectional view of a memory cell in a memory device according to a second modification example of the first embodiment;

FIG. 10 is a schematic cross-sectional view of a memory cell in a memory device according to a third modification example of the first embodiment;

FIG. 11 is a schematic cross-sectional view of a memory cell in a memory device according to a fourth modification example of the first embodiment;

FIG. 12 is a diagram showing the distribution of the normalized additive concentration of a switching layer in the fourth modification example of the first embodiment;

FIG. 13 is a schematic cross-sectional view of a memory cell in a memory device according to a second embodiment;

FIG. 14 is a diagram showing the distribution of the normalized additive concentration of a switching layer in the second embodiment;

FIG. 15 is a schematic cross-sectional view of a memory cell in a memory device according to a modification example of the second embodiment;

FIG. 16 is a diagram showing the distribution of the normalized additive concentration of a switching layer in the modification example of the second embodiment;

FIG. 17 is a schematic cross-sectional view of a memory cell in a memory device according to a third embodiment;

FIG. 18 is a diagram showing the distribution of the normalized additive concentration of a switching layer in the third embodiment;

FIG. 19 is a schematic cross-sectional view of a memory cell in a memory device according to a modification example of the third embodiment;

FIG. 20 is a diagram showing the distribution of the normalized additive concentration of a switching layer in the modification example of the third embodiment;

FIG. 21 is a schematic cross-sectional view of a memory cell in a memory device according to a fourth embodiment;

FIG. 22 is a schematic cross-sectional view of a memory cell in a memory device according to a fifth embodiment;

FIG. 23 is an explanatory diagram of the current-voltage characteristics of a memory element in the fifth embodiment;

FIG. 24 is an explanatory diagram of a first operation example of a memory operation of the memory device according to the fifth embodiment;

FIG. 25 is an explanatory diagram of a second operation example of the memory operation of the memory device according to the fifth embodiment;

FIG. 26 is an explanatory diagram of the current-voltage characteristics of a memory element in a first modification example of the fifth embodiment;

FIG. 27 is an explanatory diagram of a third operation example of a memory operation of a memory device according to the first modification example of the fifth embodiment;

FIG. 28 is an explanatory diagram of a fourth operation example of the memory operation of the memory device according to the first modification example of the fifth embodiment;

FIG. 29 is an explanatory diagram of the current-voltage characteristics of a memory element in a second modification example of the fifth embodiment;

FIG. 30 is an explanatory diagram of a fifth operation example of a memory operation of a memory device according to the second modification example of the fifth embodiment;

FIG. 31 is an explanatory diagram of a sixth operation example of the memory operation of the memory device according to the second modification example of the fifth embodiment;

FIG. 32 is an explanatory diagram of the current-voltage characteristics of a memory element in a third modification example of the fifth embodiment;

FIG. 33 is an explanatory diagram of a seventh operation example of a memory operation of a memory device according to the third modification example of the fifth embodiment; and

FIG. 34 is an explanatory diagram of an eighth operation example of the memory operation of the memory device according to the third modification example of the fifth embodiment.

### DETAILED DESCRIPTION

A memory device of embodiments includes a memory cell including a first conductive layer, a second conductive layer, a third conductive layer provided between the first conductive layer and the second conductive layer, a switching layer provided between the first conductive layer and the third conductive layer, and a variable resistance layer provided between the third conductive layer and the second conductive layer. The switching layer contains an oxide, a nitride, or an oxynitride of a first element being at least one element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg), a second element being different from the first element, and being at least one element selected from a group consisting of aluminum (Al), zinc (Zn), tin (Sn), gallium (Ga), and indium (In), and a third element being at least one element selected from a group consisting of tellurium (Te), sulfur (S), selenium (Se), and antimony (Sb). The switching layer includes a first region and a second region, and the second region is provided either between the first region and the first conductive layer or between the first region and the third conductive layer. Assuming that a sum of an atomic concentration of the first element, an atomic concentration of the second element, an atomic concentration of the third element, an atomic concentration of oxygen (O), and an atomic concentration of nitrogen (N) is a summed concentration, a first concentration obtained by dividing a sum of an atomic concentration of the second element and an atomic concentration of the third element in the first region by the summed concentration is higher than a second concentration obtained by dividing a sum of an atomic concentration of the second element and an atomic concentration of the third element in the second region by the summed concentration.

Hereinafter, embodiments will be described with reference to the diagrams. In addition, in the following description, the same or similar members and the like are denoted by the same reference numerals, and the description of the members and the like once described will be omitted as appropriate.

For the qualitative analysis and quantitative analysis of the chemical composition forming the memory device in this specification, for example, Rutherford backscattering spectroscopy (RBS), secondary ion mass spectroscopy (SIMS), energy dispersive X-ray spectroscopy (EDS), and electron energy loss spectroscopy (EELS) can be used. In addition, when measuring the thickness of each member forming the memory device, a distance between members, and the like, for example, a transmission electron microscope (TEM) can be used. In addition, for example, X-ray photoelectron spectroscopy (XPS), X-ray absorption fine structure (XAFS), Raman spectroscopy (Raman), scanning transmission electron microscope (STEM), or EELS can be used to identify the constituent materials of each member forming the memory device, measure the abundance ratio of the constituent materials, identify the bonding state of the constituent materials, identify the local structure (atomic distance, coordination number) of the constituent materials, measure the chemical state of the constituent materials, and compare the concentrations of the constituent materials.

### First Embodiment

A memory device according to a first embodiment includes a memory cell including a first conductive layer, a second conductive layer, a third conductive layer provided between the first conductive layer and the second conductive layer, a switching layer provided between the first conductive layer and the third conductive layer, and a variable resistance layer provided between the third conductive layer and the second conductive layer. The switching layer contains an oxide, a nitride, or an oxynitride of a first element being at least one element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg), a second element being different from the first element, and at least one element selected from a group consisting of aluminum (Al), zinc (Zn), tin (Sn), gallium (Ga), and indium (In), and a third element being at least one element selected from a group consisting of tellurium (Te), sulfur(S), selenium (Se), and antimony (Sb). The switching layer includes a first region and a second region, and the second region is provided either between the first region and the first conductive layer or between the first region and the third conductive layer. Assuming that a sum of an atomic concentration of the first element, an atomic concentration of the second element, an atomic concentration of the third element, an atomic concentration of oxygen (O), and an atomic concentration of nitrogen (N) is a summed concentration, a first concentration obtained by dividing a sum of an atomic concentration of the second element and an atomic concentration of the third element in the first region by the summed concentration is higher than a second concentration obtained by dividing a sum of an atomic concentration of the second element and an atomic concentration of the third element in the second region by the summed concentration.

In addition, the memory device according to the first embodiment further includes a plurality of first wirings and a plurality of second wirings crossing the plurality of first wirings. In addition, the memory cell is provided in a region where one of the plurality of first wirings and one of the plurality of second wirings cross each other.

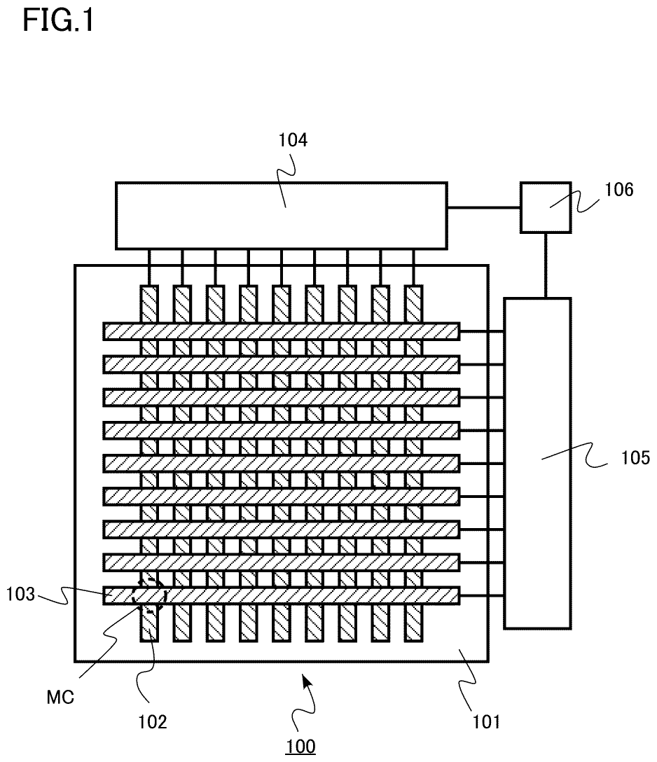

FIG. 1 is a block diagram of the memory device according to the first embodiment.

A memory cell array 100 in the memory device according to the first embodiment includes, for example, a plurality of word lines 102 and a plurality of bit lines 103 crossing the word lines 102 on a semiconductor substrate 101 with an insulating layer interposed therebetween. The bit lines 103 are provided in a layer above the word lines 102, for example. In addition, a first control circuit 104, a second control circuit 105, and a sense circuit 106 are provided as peripheral circuits around the memory cell array 100.

The word line 102 is an example of the first wiring. In addition, the bit line 103 is an example of the second wiring.

A plurality of memory cells MC are provided in regions where the word lines 102 and the bit lines 103 cross each other. The memory device according to the first embodiment is a two-terminal magnetoresistive memory having a cross-point structure.

Each of the plurality of word lines 102 is connected to the first control circuit 104. In addition, each of the plurality of bit lines 103 is connected to the second control circuit 105. The sense circuit 106 is connected to the first control circuit 104 and the second control circuit 105.

The first control circuit 104 and the second control circuit 105 have functions of selecting a desired memory cell MC, writing data to the memory cell MC, reading data from the memory cell MC, and deleting data from the memory cell MC, for example. When reading data, the data in the memory cell MC is read as the amount of current flowing between the word line 102 and the bit line 103 or as an electric potential change of the bit line 103. The sense circuit 106 has a function of determining the amount of current to determine the polarity of the data. For example, “0” and “1” of data are determined.

The first control circuit 104, the second control circuit 105, and the sense circuit 106 are electronic circuits using semiconductor devices formed on the semiconductor substrate 101, for example.

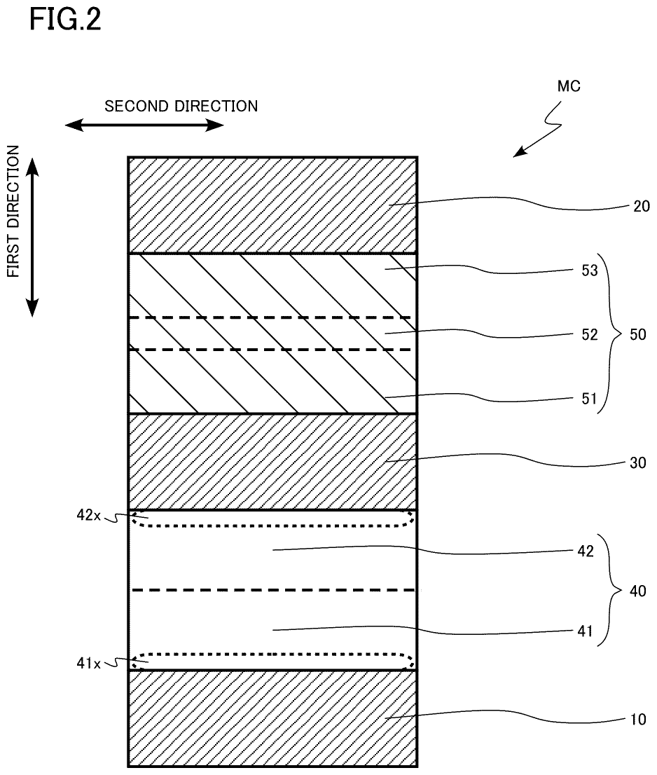

FIG. 2 is a schematic cross-sectional view of a memory cell in the memory device according to the first embodiment. FIG. 2 shows a cross section of one memory cell MC indicated by, for example, a dotted circle in the memory cell array 100 of FIG. 1. FIG. 2 shows a cross section parallel to a first direction connecting a lower electrode 10 and an upper electrode 20.

As shown in FIG. 2, the memory cell MC includes the lower electrode 10, the upper electrode 20, an intermediate electrode 30, a switching layer 40, and a variable resistance layer 50. The switching layer 40 includes a high concentration region 41 and a medium concentration region 42. The high concentration region 41 includes a first contact portion 41x. The medium concentration region 42 includes a second contact portion 42x.

The lower electrode 10 is an example of the first conductive layer. The upper electrode 20 is an example of the second conductive layer. The intermediate electrode 30 is an example of the third conductive layer. The high concentration region 41 is an example of the first region. The medium concentration region 42 is an example of the second region. The first contact portion 41x is an example of the first portion. The second contact portion 42x is an example of the second portion.

The lower electrode 10, the switching layer 40, and the intermediate electrode 30 form a switching element of the memory cell MC. The intermediate electrode 30, the variable resistance layer 50, and the upper electrode 20 form a variable resistance element of the memory cell MC.

The lower electrode 10 is connected to the word line 102. The lower electrode 10 is, for example, a metal. The lower electrode 10 contains, for example, at least one material selected from a group consisting of carbon, carbon nitride, tungsten, tungsten carbide, tungsten nitride, titanium, titanium nitride, tantalum, tantalum carbide, and tantalum nitride. The lower electrode 10 may be a part of the word line 102.

The upper electrode 20 is connected to the bit line 103. The upper electrode 20 is, for example, a metal. The upper electrode 20 contains, for example, at least one material selected from a group consisting of carbon, carbon nitride, tungsten, tungsten carbide, tungsten nitride, titanium, titanium nitride, tantalum, tantalum carbide, and tantalum nitride. The upper electrode 20 may be a part of the bit line 103.

The intermediate electrode 30 is provided between the lower electrode 10 and the upper electrode 20. The intermediate electrode 30 is, for example, a metal. The intermediate electrode 30 contains, for example, at least one material selected from a group consisting of carbon, carbon nitride, tungsten, tungsten carbide, tungsten nitride, titanium, titanium nitride, tantalum, tantalum carbide, and tantalum nitride.

The switching layer 40 is provided between the lower electrode 10 and the intermediate electrode 30. The thickness of the switching layer 40 in a first direction from the lower electrode 10 to the upper electrode 20 is, for example, equal to or more than 4 nm and equal to or less than 25 nm. The length of the switching layer 40 in a second direction perpendicular to the first direction is, for example, equal to or more than 10 nm and equal to or less than 50 nm.

The switching layer 40 has a function of suppressing an increase in half-select leakage current flowing through a half-selected cell. The switching layer 40 has a nonlinear current-voltage characteristic that a current increases abruptly at a specific threshold voltage.

The switching layer 40 contains a first oxide, a nitride, or an oxynitride of a first element. The switching layer 40 contains a second element and a third element. The switching layer 40 contains at least one of oxygen (O) and nitrogen (N). Hereinafter, the second element and the third element may be referred to as additives.

The first element is at least one element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg).

The oxide of the first element is, for example, an aluminum oxide, a silicon oxide, a germanium oxide, a zirconium oxide, a yttrium oxide, a tantalum oxide, a lanthanum oxide, a cerium oxide, a titanium oxide, a hafnium oxide, or a magnesium oxide. The nitride of the first element is, for example, an aluminum nitride, a silicon nitride, a germanium nitride, a zirconium nitride, a yttrium nitride, a tantalum nitride, a lanthanum nitride, a cerium nitride, a titanium nitride, a hafnium nitride, or a magnesium nitride. The oxynitride of the first element is, for example, an aluminum oxynitride, a silicon oxynitride, a germanium oxynitride, a zirconium oxynitride, a yttrium oxynitride, a tantalum oxynitride, a lanthanum oxynitride, a cerium oxynitride, a titanium oxynitride, a hafnium oxynitride, or a magnesium oxynitride.

The second element is an element different from the first element. The second element is at least one element selected from a group consisting of aluminum (Al), zinc (Zn), tin (Sn), gallium (Ga), and indium (In). The third element is at least one element selected from a group consisting of tellurium (Te), sulfur(S), selenium (Se), and antimony (Sb).

In addition, it is also possible to select bismuth (Bi) as the second element.

The switching layer 40 contains, for example, a compound of the second element and the third element. The compound of the second element and the third element is, for example, aluminum telluride, zinc telluride, tin telluride, gallium telluride, indium telluride, aluminum sulfide, zinc sulfide, tin sulfide, gallium sulfide, indium sulfide, aluminum selenide, zinc selenide, tin selenide, gallium selenide, indium selenide, aluminum antimonide, zinc antimonide, tin antimonide, gallium antimonide, or indium antimonide.

The switching layer 40 may contain, for example, bismuth telluride, bismuth sulfide, bismuth selenide, or bismuth antimonide.

The sum of the atomic concentration of the first element, the atomic concentration of the second element, the atomic concentration of the third element, the atomic concentration of oxygen (O), and the atomic concentration of nitrogen (N) in the switching layer 40 is referred to as a summed concentration. The summed concentration of the switching layer 40 is, for example, equal to or more than 80% and equal to or less than 100%.

The sum of the atomic concentration of the second element and the atomic concentration of the third element in the switching layer 40 is referred to as an additive concentration. A concentration obtained by dividing the additive concentration by the summed concentration is referred to as a normalized additive concentration. The normalized additive concentration of the switching layer 40 is, for example, equal to or more than 0.1% and equal to or less than 99%.

The switching layer 40 includes the high concentration region 41 and the medium concentration region 42. The medium concentration region 42 is provided between the high concentration region 41 and the intermediate electrode 30.

The high concentration region 41 is in contact with, for example, the lower electrode 10. A portion of the high concentration region 41 in contact with the lower electrode 10 is the first contact portion 41x.

The medium concentration region 42 is in contact with, for example, the intermediate electrode 30. A portion of the medium concentration region 42 in contact with the intermediate electrode 30 is the second contact portion 42x.

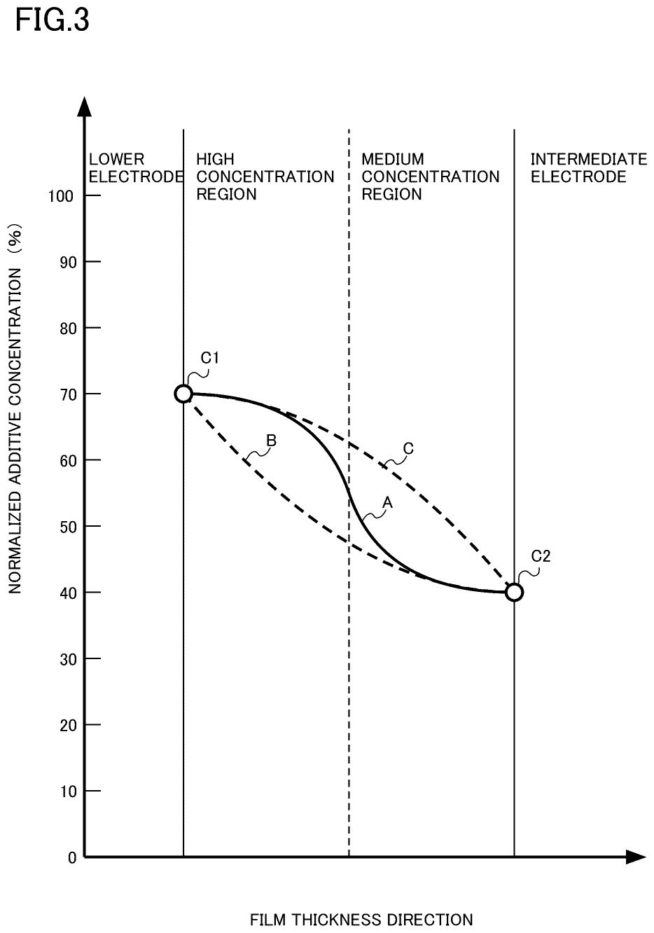

FIG. 3 is a diagram showing the distribution of the normalized additive concentration of the switching layer in the first embodiment. FIG. 3 shows the distribution of normalized additive concentration in the film thickness direction. The film thickness direction is the first direction.

For example, in the analysis of chemical composition using TEM and EDS or EELS, an electron beam acceleration voltage of 200 kV, a beam current of 100 pA to 1 nA, and a beam diameter for a spatial resolution of about 1 nm are applied as the TEM conditions. For example, by continuously measuring the chemical composition of the switching layer 40 at intervals equal to or less than 1 nm in the film thickness direction of the switching layer 40 of the measurement sample using the above TEM conditions and calculating the normalized additive concentration, the distribution of normalized additive concentration shown in FIG. 3 can be obtained.

The first concentration, which is a normalized additive concentration of the high concentration region 41, is higher than the second concentration, which is a normalized additive concentration of the medium concentration region 42.

The difference between the first concentration (C1 in FIG. 3) of the first contact portion 41x of the high concentration region 41 and the second concentration (C2 in FIG. 3) of the second contact portion 42x of the medium concentration region 42 is, for example, equal to or more than 10% and equal to or less than 70%.

The first concentration C1 of the first contact portion 41x of the high concentration region 41 is, for example, equal to or more than 40% and equal to or less than 99%. The second concentration C2 of the second contact portion 42x of the medium concentration region 42 is, for example, equal to or more than 30% and equal to or less than 70%.

The normalized additive concentration of the switching layer 40 monotonically decreases from the lower electrode 10 to the intermediate electrode 30, for example. The normalized additive concentration portion of the switching layer 40 has a distribution indicated by the solid line A, the dotted line B, or the dotted line C in FIG. 3, for example.

The variable resistance layer 50 is provided between the intermediate electrode 30 and the upper electrode 20. The variable resistance layer 50 includes a fixed layer 51, a tunnel layer 52, and a free layer 53. The variable resistance layer 50 includes a magnetic tunnel junction formed by the fixed layer 51, the tunnel layer 52, and the free layer 53.

The variable resistance layer 50 has a function of storing data by resistance change. The variable resistance layer 50 has, for example, a characteristic that the electrical resistance changes with the application of a predetermined voltage.

The fixed layer 51 is a ferromagnetic material. In the fixed layer 51, its magnetization direction does not change with respect to a predetermined write voltage, but is fixed to a specific direction.

The tunnel layer 52 is an insulator. Electrons pass through the tunnel layer 52 by the tunnel effect.

The free layer 53 is a ferromagnetic material. In the free layer 53, its magnetization direction changes with respect to a predetermined write voltage. The magnetization direction of the free layer 53 can be parallel to the magnetization direction of the fixed layer 51 or can be antiparallel to the magnetization direction of the fixed layer 51. For example, by applying a voltage between the intermediate electrode 30 and the upper electrode 20 so that a current flows between the intermediate electrode 30 and the upper electrode 20, the magnetization direction of the free layer 53 can be changed.

By changing the magnetization direction of the free layer 53, the electrical resistance of the variable resistance layer 50 changes. When the magnetization direction of the free layer 53 is antiparallel to the magnetization direction of the fixed layer 51, a high resistance state in which a current hardly flows is realized. On the other hand, when the magnetization direction of the free layer 53 is parallel to the magnetization direction of the fixed layer 51, a low resistance state in which a current flows easily is realized. In addition, the arrangement of the fixed layer 51 and the free layer 53 may be reversed. That is, the intermediate electrode 30, the free layer 53, the tunnel layer 52, the fixed layer 51, and the upper electrode 20 may be stacked in this order.

Next, the function and effect of the memory device according to the first embodiment will be described.

In the memory device according to the first embodiment, the resistance of the variable resistance layer 50 is changed by changing the magnetization direction of the free layer 53 as described above. When the magnetization direction of the free layer 53 is antiparallel to the magnetization direction of the fixed layer 51, a high resistance state in which a current hardly flows is realized. On the other hand, when the magnetization direction of the free layer 53 is parallel to the magnetization direction of the fixed layer 51, a low resistance state in which a current flows easily is realized.

For example, the high resistance state of the variable resistance layer 50 is defined as data “1”, and the low resistance state of the variable resistance layer 50 is defined as data “0”. Since the memory cell MC can maintain different resistance states, it is possible to store 1-bit data of “0” and “1”. Writing to one memory cell MC is performed by applying a voltage between the bit line 103 and the word line 102 connected to the memory cell MC so that a current flows between the bit line 103 and the word line 102 connected to the memory cell MC.

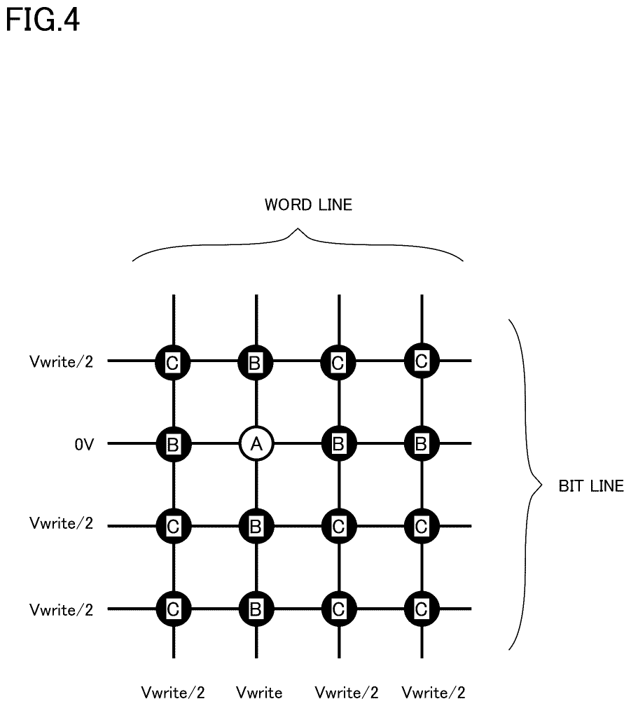

FIG. 4 is an explanatory diagram of a problem of the memory device according to the first embodiment. FIG. 4 shows a voltage applied to the memory cell MC when one memory cell MC in the memory cell array is selected for a write operation. The intersection of word lines and bit lines represents each memory cell MC.

The selected memory cell MC is a memory cell A (selected cell). A write voltage Vwrite is applied to the word line connected to the memory cell A. In addition, 0 V is applied to the bit line connected to the memory cell A.

Hereinafter, a case in which half (Vwrite/2) the write voltage is applied to the word lines and bit lines that are not connected to the memory cell A will be described as an example.

A voltage applied to memory cells C (non-selected cells) connected to the word lines and bit lines that are not connected to the memory cell A is 0 V. That is, no voltage is applied.

On the other hand, half (Vwrite/2) the write voltage Vwrite is applied to memory cells B (half-selected cells) connected to the word lines or bit lines connected to the memory cell A. Therefore, a half-select leakage current flows through the memory cell B (half-selected cell).

In addition, as an application method other than those described above, a method may be used in which half the write voltage (Vwrite/2) is applied to the word line connected to the memory cell A, a negative voltage (Vwrite/2) of half the write voltage is applied to the bit line, and 0 V is applied to the word line and the bit line that are not connected to the memory cell A.

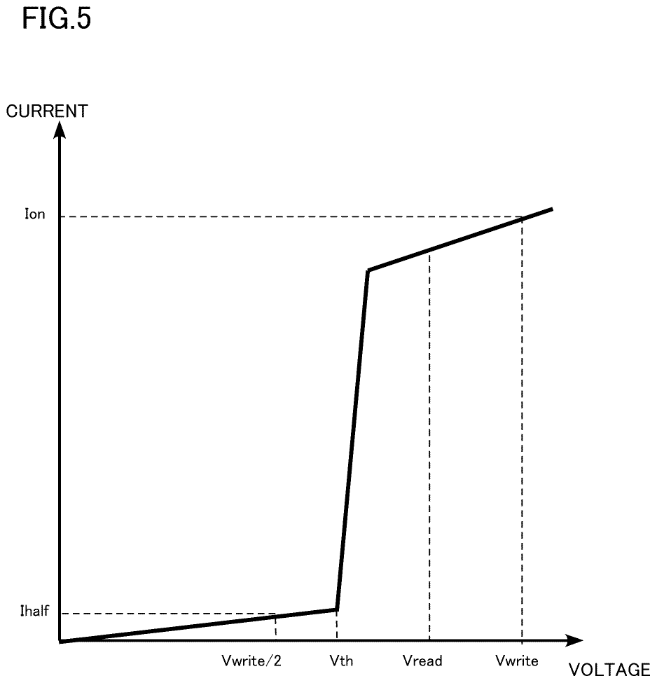

FIG. 5 is an explanatory diagram of the current-voltage characteristics of a switching element in the first embodiment. The horizontal axis indicates a voltage applied to the switching element, and the vertical axis indicates a current flowing through the switching element.

The switching element has a nonlinear current-voltage characteristic that a current increases abruptly at a threshold voltage Vth. The threshold voltage Vth is, for example, equal to or more than 0.5 V and equal to or less than 3 V.

The write voltage Vwrite is set such that the write voltage Vwrite is higher than the threshold voltage Vth and half (Vwrite/2) the write voltage Vwrite is lower than the threshold voltage Vth. The current flowing through the switching element when the write voltage Vwrite is applied is an on-current (Ion in FIG. 5). The current flowing through the switching element when half (Vwrite/2) the write voltage Vwrite is applied is a half-select leakage current (Ihalf in FIG. 5).

In addition, a read voltage Vread of the memory cell MC is set to a voltage higher than the threshold voltage Vth and lower than the write voltage Vwrite, as shown in FIG. 5, for example. Therefore, the half-select leakage current flowing through the half-selected cell can be suppressed when reading the memory cell MC.

If the half-select leakage current is large, for example, the power consumption of the chip increases. In addition, for example, a voltage drop in the wiring increases and accordingly, a sufficiently high voltage is not applied to the selected cell. As a result, an operation for writing to the memory cell MC becomes unstable. In addition, if the on-current is small, for example, the current flowing through the selected cell is insufficient, resulting in insufficient writing to the memory cell MC. Therefore, as the current-voltage characteristics of the switching element, it is required to have both a low half-select leakage current and a high on-current.

In addition, high reliability is required for the current-voltage characteristics of the switching element. For example, it is required to realize high reliability by realizing high endurance tolerance by suppressing characteristic fluctuations, such as fluctuations in half-select leakage current and fluctuations in on-current, when repeating the application of a voltage to the switching element.

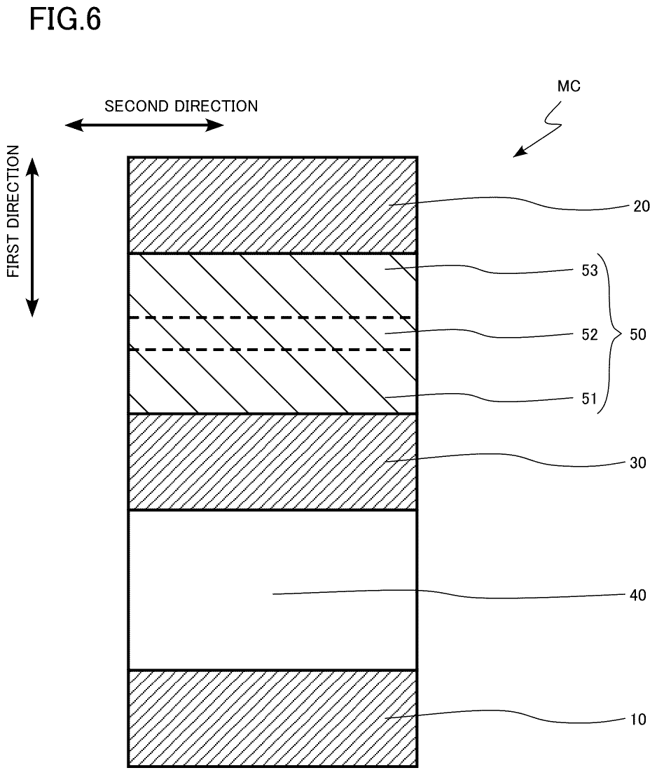

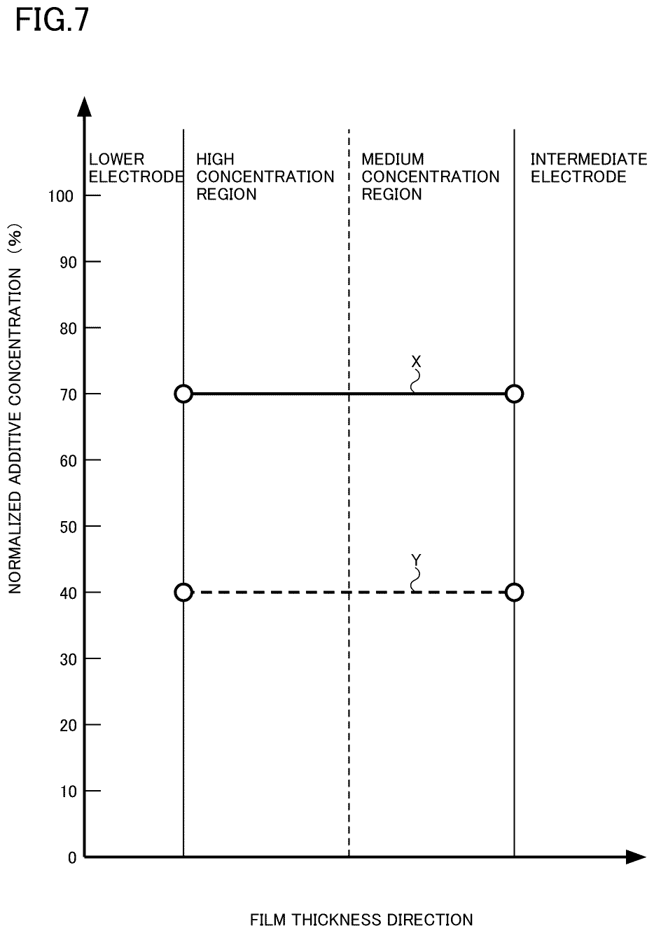

FIG. 6 is a schematic cross-sectional view of a memory cell in a memory device according to a comparative example. FIG. 7 is a diagram showing the distribution of the normalized additive concentration of the switching layer in the comparative example. FIGS. 6 and 7 are diagrams corresponding to FIGS. 2 and 3 in the first embodiment, respectively.

The memory cell MC in the memory device according to the comparative example is different from the memory cell MC in the memory device according to the first embodiment in that the normalized additive concentration of the switching layer 40 is constant in the film thickness direction, as shown by the solid line X or the dotted line Y in FIG. 7.

The switching element in the memory device according to the comparative example has a problem that its endurance tolerance is low, for example. One factor that causes the low endurance tolerance of the switching element in the comparative example is believed to be the movement of the second element and the third element due to the electric field when an electric field is applied in the film thickness direction of the switching layer 40. For example, it is believed that the movement of the second element and the third element generates defects in the switching layer 40 and characteristic fluctuations such as fluctuations in half-select leakage current and fluctuations in on-current occur due to the defects, thereby causing in a decrease in endurance tolerance.

In addition, the switching element in the comparative example has a problem that the half-select leakage current increases particularly when the normalized additive concentration of the switching layer 40 is relatively high as shown by the solid line X in FIG. 7.

In the switching element in the first embodiment, the switching layer 40 includes the high concentration region 41 and the medium concentration region 42. The first concentration, which is a normalized additive concentration of the high concentration region 41, is higher than the second concentration, which is a normalized additive concentration of the medium concentration region 42. In other words, a concentration gradient is provided in the additive concentration of the switching layer 40.

By providing a concentration gradient in the additive concentration of the switching layer 40, the endurance tolerance of the switching element in the first embodiment is increased. This is believed to be because, by providing a concentration gradient in the additive concentration of the switching layer 40, the movement of the second element and the third element due to the electric field is less likely to occur when an electric field is applied in the film thickness direction of the switching layer 40. In particular, it is believed that by providing a concentration gradient to offset the movement of the second element and the third element when an electric field is applied, the movement of the second element and the third element is suppressed and accordingly, high endurance tolerance can be realized.

From the viewpoint of suppressing the movement of the second element and the third element to realize the high endurance tolerance of the switching element, the difference between the first concentration (C1 in FIG. 3) of the first contact portion 41x of the high concentration region 41 and the second concentration (C2 in FIG. 3) of the second contact portion 42x of the medium concentration region 42 is preferably equal to or more than 10%, more preferably equal to or more than 20%, and even more preferably equal to or more than 30%.

According to the first embodiment, since the endurance tolerance of the switching element is improved, it is possible to realize a switching element with excellent characteristics. Therefore, it is possible to realize a memory device having a switching element with excellent characteristics.

### First Modification Example

A memory device according to a first modification example of the first embodiment is different from the memory device according to the first embodiment in that the first conductive layer includes a first portion and a second portion and the first portion contains at least one element selected from hafnium (Hf), aluminum (Al), magnesium (Mg), zirconium (Zr), and titanium (Ti).

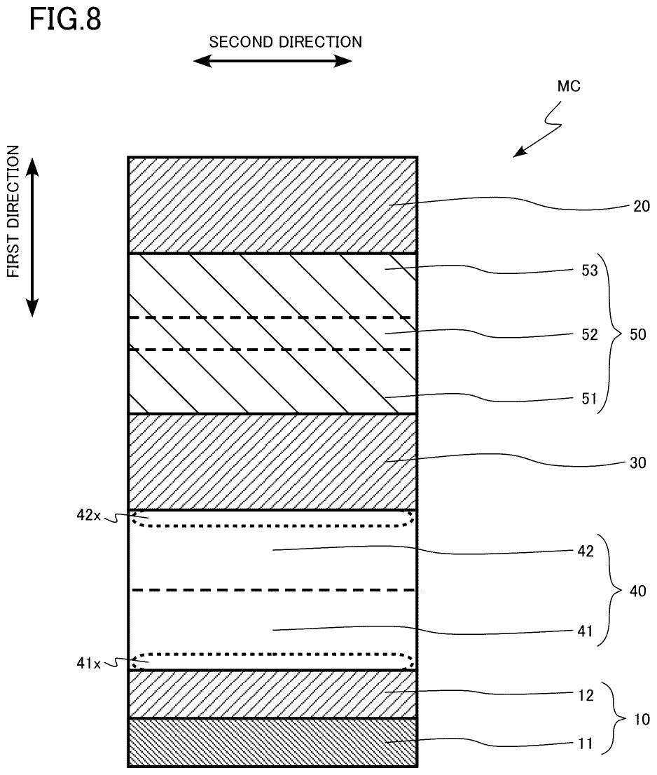

FIG. 8 is a schematic cross-sectional view of a memory cell in the memory device according to the first modification example of the first embodiment. FIG. 8 is a diagram corresponding to FIG. 2 in the first embodiment.

The lower electrode 10 includes a first portion 11 and a second portion 12. The second portion 12 is provided between the first portion 11 and the switching layer 40.

The first portion 11 contains at least one element selected from hafnium (Hf), aluminum (Al), magnesium (Mg), zirconium (Zr), and titanium (Ti). The first portion 11 contains, for example, borides of the above elements. The first portion 11 contains, for example, at least one material selected from a group consisting of hafnium, hafnium boride, aluminum magnesium boride, zirconium, zirconium boride, and titanium boride.

The second portion 12 contains, for example, at least one material selected from a group consisting of carbon, carbon nitride, tungsten, tungsten carbide, tungsten nitride, titanium, titanium nitride, tantalum, tantalum carbide, and tantalum nitride.

In the memory device according to the first modification example of the first embodiment, since the first portion 11 of the lower electrode 10 contains at least one element selected from hafnium (Hf), aluminum (Al), magnesium (Mg), zirconium (Zr), and titanium (Ti), degradation of the characteristics of the variable resistance element is suppressed. In addition, since the first portion 11 is not in contact with the switching layer 40, desorption of oxygen (O) from the switching layer 40 is suppressed and accordingly, degradation of the characteristics of the switching element is suppressed.

As described above, according to the first modification example of the first embodiment, it is possible to realize a switching element with excellent characteristics as in the first embodiment. Therefore, it is possible to realize a memory device having a switching element with excellent characteristics.

### Second Modification Example

A memory device according to a second modification example of the first embodiment is different from the memory device according to the first embodiment in that the first conductive layer includes a first portion and a second portion, the first portion contains at least one element selected from hafnium (Hf), aluminum (Al), magnesium (Mg), zirconium (Zr), and titanium (Ti), the second conductive layer contains one element selected from hafnium (Hf), aluminum (Al), magnesium (Mg), zirconium (Zr), and titanium (Ti), the third conductive layer includes a third portion and a fourth portion, and the fourth portion contains at least one element selected from hafnium (Hf), aluminum (Al), magnesium (Mg), zirconium (Zr), and titanium (Ti).

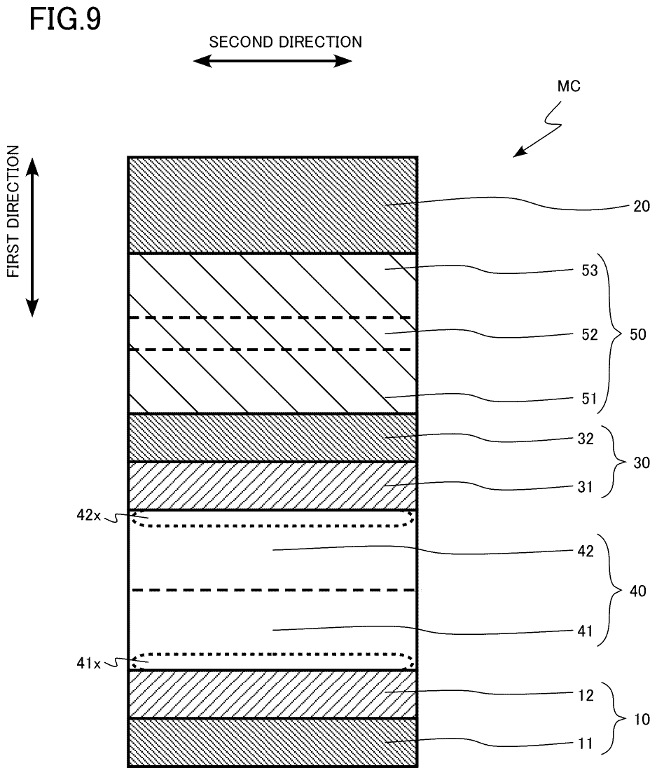

FIG. 9 is a schematic cross-sectional view of a memory cell in the memory device according to the second modification example of the first embodiment. FIG. 9 is a diagram corresponding to FIG. 2 in the first embodiment.

The lower electrode 10 includes a first portion 11 and a second portion 12. The second portion 12 is provided between the first portion 11 and the switching layer 40.

The first portion 11 contains at least one element selected from hafnium (Hf), aluminum (Al), magnesium (Mg), zirconium (Zr), and titanium (Ti). The first portion 11 contains, for example, borides of the above elements. The first portion 11 contains, for example, at least one material selected from a group consisting of hafnium, hafnium boride, magnesium aluminum boride, zirconium, zirconium boride, and titanium boride.

The second portion 12 contains, for example, at least one material selected from a group consisting of carbon, carbon nitride, tungsten, tungsten carbide, tungsten nitride, titanium, titanium nitride, tantalum, tantalum carbide, and tantalum nitride.

The upper electrode 20 contains at least one element selected from hafnium (Hf), aluminum (Al), magnesium (Mg), zirconium (Zr), and titanium (Ti). The upper electrode 20 contains, for example, borides of the above elements. The upper electrode 20 contains, for example, at least one material selected from a group consisting of hafnium, hafnium boride, magnesium aluminum boride, zirconium, zirconium boride, and titanium boride.

The intermediate electrode 30 includes a third portion 31 and a fourth portion 32. The third portion 31 is provided between the fourth portion 32 and the switching layer 40.

The third portion 31 contains, for example, at least one material selected from a group consisting of carbon, carbon nitride, tungsten, tungsten carbide, tungsten nitride, titanium, titanium nitride, tantalum, tantalum carbide, and tantalum nitride.

The fourth portion 32 contains at least one element selected from hafnium (Hf), aluminum (Al), magnesium (Mg), zirconium (Zr), and titanium (Ti). The fourth portion 32 contains, for example, borides of the above elements. The fourth portion 32 contains, for example, at least one material selected from a group consisting of hafnium, hafnium boride, magnesium aluminum boride, zirconium, zirconium boride, and titanium boride.

In the memory device according to the second modification example of the first embodiment, since the first portion 11 of the lower electrode 10, the upper electrode 20, and the fourth portion 32 of the intermediate electrode 30 contain at least one element selected from hafnium (Hf), aluminum (Al), magnesium (Mg), zirconium (Zr), and titanium (Ti), degradation of the characteristics of the variable resistance element is suppressed. In addition, since the first portion 11 of the lower electrode 10, the upper electrode 20, and the fourth portion 32 of the intermediate electrode 30 are not in contact with the switching layer 40, desorption of oxygen (O) from the switching layer 40 is suppressed and accordingly, degradation of the characteristics of the switching element is suppressed.

As described above, according to the second modification example of the first embodiment, it is possible to realize a switching element with excellent characteristics as in the first embodiment. Therefore, it is possible to realize a memory device having a switching element with excellent characteristics.

### Third Modification Example

A memory device according to a third modification example of the first embodiment is different from the memory device according to the first embodiment in that the first conductive layer includes a first portion, a second portion, and a fifth portion, the first portion contains at least one element selected from hafnium (Hf), aluminum (Al), magnesium (Mg), zirconium (Zr), and titanium (Ti), the second conductive layer contains at least one element selected from hafnium (Hf), aluminum (Al), magnesium (Mg), zirconium (Zr), and titanium (Ti), the third conductive layer includes a third portion and a fourth portion, and the fourth portion contains at least one element selected from hafnium (Hf), aluminum (Al), magnesium (Mg), zirconium (Zr), and titanium (Ti).

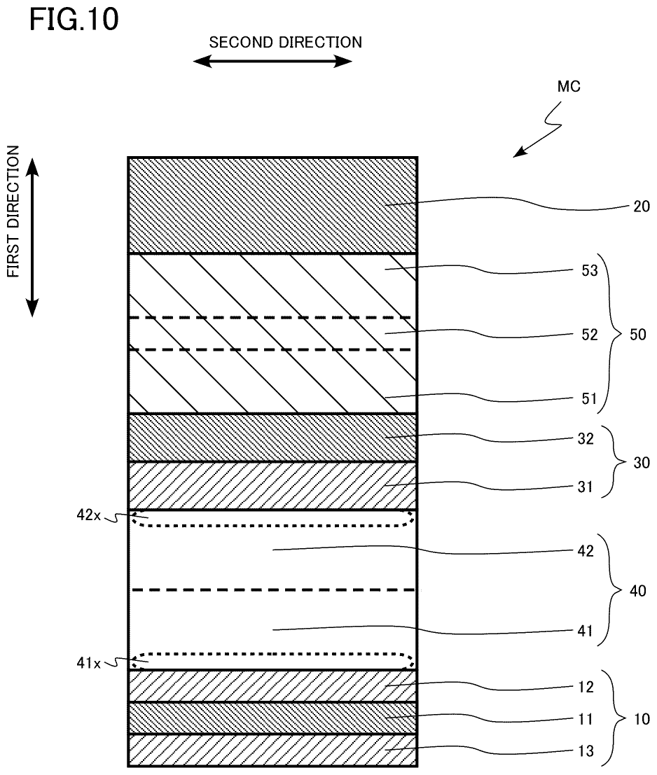

FIG. 10 is a schematic cross-sectional view of a memory cell in the memory device according to the third modification example of the first embodiment. FIG. 10 is a diagram corresponding to FIG. 2 in the first embodiment.

The lower electrode 10 includes a first portion 11, a second portion 12, and a fifth portion 13. The second portion 12 is provided between the first portion 11 and the switching layer 40. The first portion 11 is provided between the fifth portion 13 and the second portion 12.

The first portion 11 contains at least one element selected from hafnium (Hf), aluminum (Al), magnesium (Mg), zirconium (Zr), and titanium (Ti). The first portion 11 contains, for example, borides of the above elements. The first portion 11 contains, for example, at least one material selected from a group consisting of hafnium, hafnium boride, magnesium aluminum boride, zirconium, zirconium boride, and titanium boride.

The second portion 12 and the fifth portion 13 contain, for example, at least one material selected from a group consisting of carbon, carbon nitride, tungsten, tungsten carbide, tungsten nitride, titanium, titanium nitride, tantalum, tantalum carbide, and tantalum nitride.

The upper electrode 20 contains at least one element selected from hafnium (Hf), aluminum (Al), magnesium (Mg), zirconium (Zr), and titanium (Ti). The upper electrode 20 contains, for example, borides of the above elements. The upper electrode 20 contains, for example, at least one material selected from a group consisting of hafnium, hafnium boride, magnesium aluminum boride, zirconium, zirconium boride, and titanium boride.

The intermediate electrode 30 includes a third portion 31 and a fourth portion 32. The third portion 31 is provided between the fourth portion 32 and the switching layer 40.

The third portion 31 contains, for example, at least one material selected from a group consisting of carbon, carbon nitride, tungsten, tungsten carbide, tungsten nitride, titanium, titanium nitride, tantalum, tantalum carbide, and tantalum nitride.

The fourth portion 32 contains at least one element selected from hafnium (Hf), aluminum (Al), magnesium (Mg), zirconium (Zr), and titanium (Ti). The fourth portion 32 contains, for example, borides of the above elements. The fourth portion 32 contains, for example, at least one material selected from a group consisting of hafnium, hafnium boride, magnesium aluminum boride, zirconium, zirconium boride, and titanium boride.

In the memory device according to the third modification example of the first embodiment, since the first portion 11 of the lower electrode 10, the upper electrode 20, and the fourth portion 32 of the intermediate electrode 30 contain at least one element selected from hafnium (Hf), aluminum (Al), magnesium (Mg), zirconium (Zr), and titanium (Ti), degradation of the characteristics of the variable resistance element is suppressed. In addition, since the first portion 11 of the lower electrode 10, the upper electrode 20, and the fourth portion 32 of the intermediate electrode 30 are not in contact with the switching layer 40, desorption of oxygen (O) from the switching layer 40 is suppressed and accordingly, degradation of the characteristics of the switching element is suppressed.

As described above, according to the third modification example of the first embodiment, it is possible to realize a switching element with excellent characteristics as in the first embodiment. Therefore, it is possible to realize a memory device having switching elements with excellent characteristics.

### Fourth Modification Example

A memory device according to a fourth modification example of the first embodiment is different from the memory device according to the first embodiment in that the second region is provided between the first region and the first conductive layer.

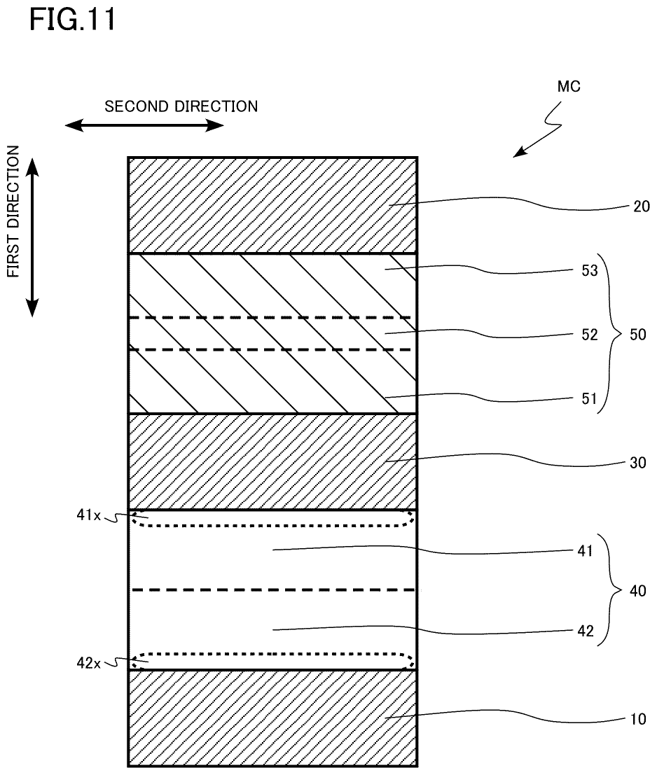

FIG. 11 is a schematic cross-sectional view of a memory cell in the memory device according to the fourth modification example of the first embodiment. FIG. 11 is a diagram corresponding to FIG. 2 in the first embodiment.

The switching layer 40 includes a high concentration region 41 and a medium concentration region 42. The medium concentration region 42 is provided between the high concentration region 41 and the lower electrode 10.

The high concentration region 41 is in contact with, for example, the intermediate electrode 30. A portion of the high concentration region 41 in contact with the intermediate electrode 30 is the first contact portion 41x.

The medium concentration region 42 is in contact with, for example, the lower electrode 10. A portion of the medium concentration region 42 in contact with the lower electrode 10 is the second contact portion 42x.

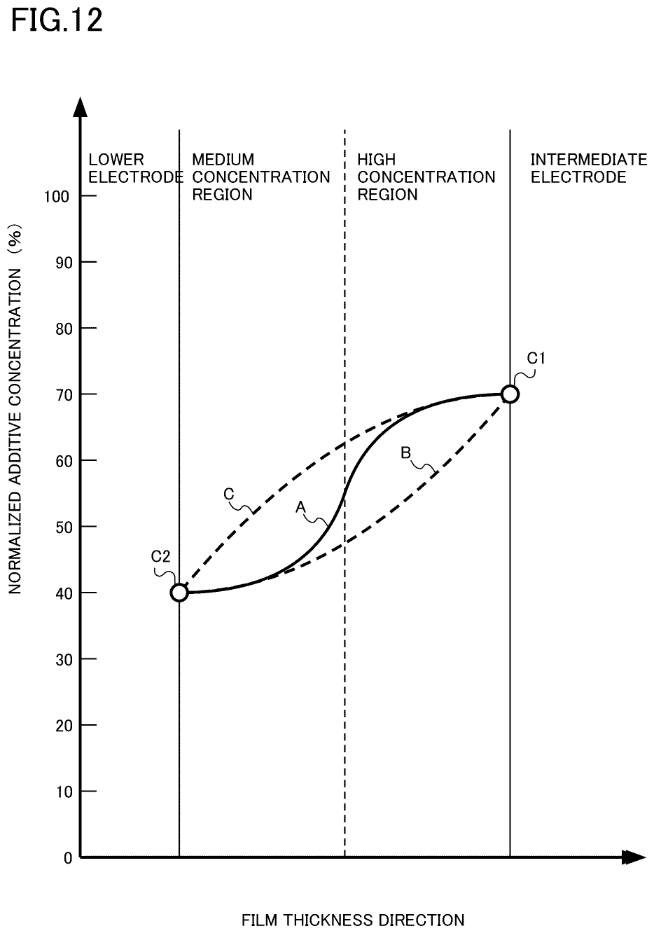

FIG. 12 is a diagram showing the distribution of the normalized additive concentration of the switching layer in the fourth modification example of the first embodiment. FIG. 12 shows the distribution of normalized additive concentration in the film thickness direction. The film thickness direction is the first direction. FIG. 12 is a diagram corresponding to FIG. 3 in the first embodiment.

The difference between the first concentration (C1 in FIG. 12) of the first contact portion 41x of the high concentration region 41 and the second concentration (C2 in FIG. 12) of the second contact portion 42x of the medium concentration region 42 is, for example, equal to or more than 10% and equal to or less than 70%.

The first concentration C1 of the first contact portion 41x of the high concentration region 41 is, for example, equal to or more than 40% and equal to or less than 99%. The second concentration C2 of the second contact portion 42x of the medium concentration region 42 is, for example, equal to or more than 30% and equal to or less than 70%.

The normalized additive concentration of the switching layer 40 monotonically increases from the lower electrode 10 to the intermediate electrode 30, for example. The normalized additive concentration portion of the switching layer 40 has a distribution indicated by the solid line A, the dotted line B, or the dotted line C in FIG. 12, for example.

As described above, according to the fourth modification example of the first embodiment, a switching element with excellent characteristics can be realized. Therefore, a memory device having switching elements with excellent characteristics can be realized.

According to the first embodiment and its modification examples, since the endurance tolerance of the switching element is improved, it is possible to realize a switching element with excellent characteristics. Therefore, according to the first embodiment and its modification examples, it is possible to realize a memory device having a switching element with excellent characteristics.

### Second Embodiment

A memory device according to a second embodiment is different from the memory device according to the first embodiment in that the first portion of the first region is in contact with the third conductive layer, the second portion of the second region is in contact with the first conductive layer, the first concentration of the first portion is equal to or more than 20%, and the second concentration of the second portion is less than 30%. Hereinafter, the description of a part of the content overlapping the first embodiment may be omitted.

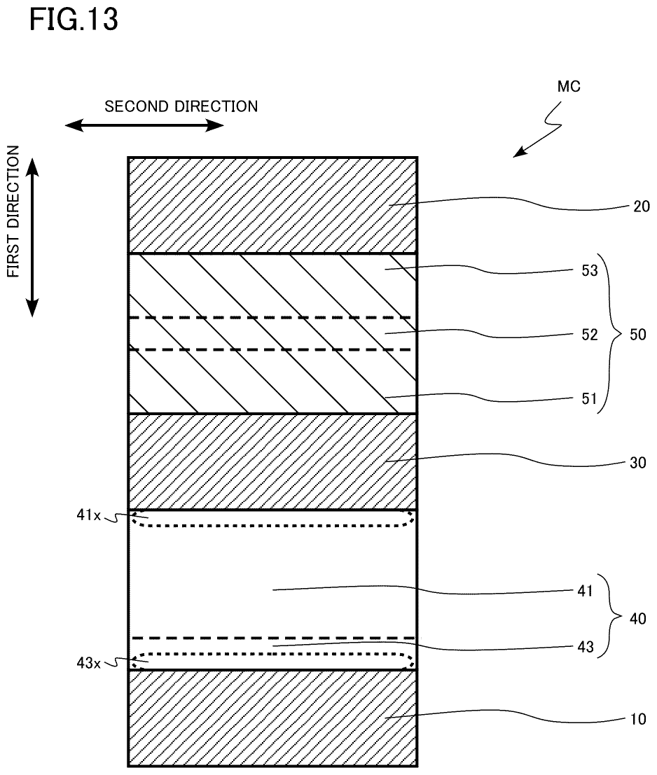

FIG. 13 is a schematic cross-sectional view of a memory cell in the memory device according to the second embodiment. FIG. 13 is a diagram corresponding to FIG. 2 in the first embodiment.

As shown in FIG. 13, the memory cell MC includes a lower electrode 10, an upper electrode 20, an intermediate electrode 30, a switching layer 40, and a variable resistance layer 50. The switching layer 40 includes a high concentration region 41 and a low concentration region 43. The high concentration region 41 includes a first contact portion 41x. The low concentration region 43 includes a third contact portion 43x.

The lower electrode 10 is an example of the first conductive layer. The upper electrode 20 is an example of the second conductive layer. The intermediate electrode 30 is an example of the third conductive layer. The high concentration region 41 is an example of the first region. The low concentration region 43 is an example of the second region. The first contact portion 41x is an example of the first portion. The third contact portion 43x is an example of the second portion.

The switching layer 40 includes a high concentration region 41 and a low concentration region 43. The low concentration region 43 is provided between the high concentration region 41 and the lower electrode 10.

The high concentration region 41 is in contact with, for example, the intermediate electrode 30. A portion of the high concentration region 41 in contact with the intermediate electrode 30 is the first contact portion 41x.

The low concentration region 43 is in contact with, for example, the lower electrode 10. A portion of the low concentration region 43 in contact with the lower electrode 10 is the third contact portion 43x.

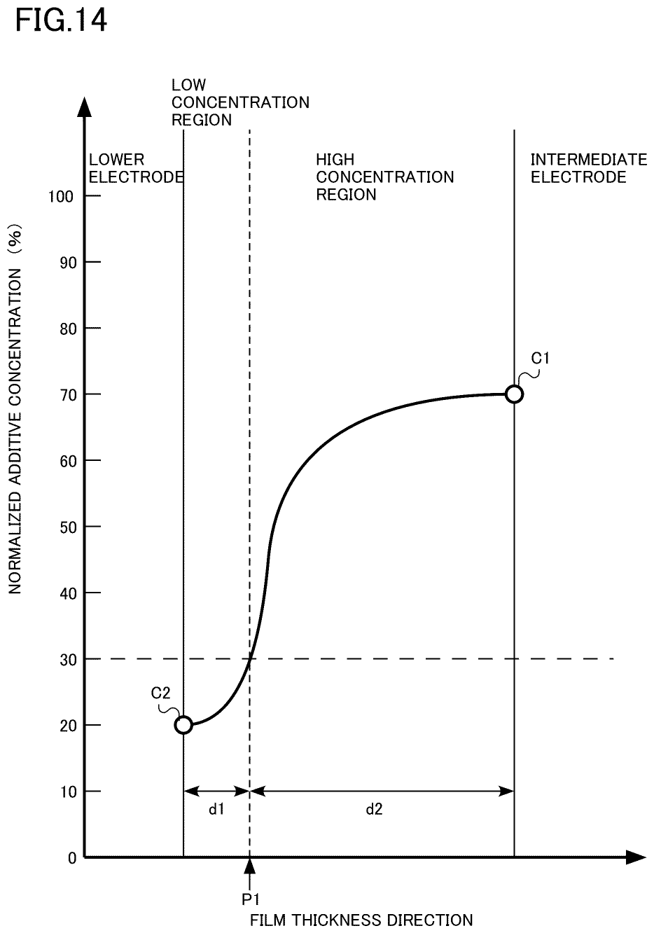

FIG. 14 is a diagram showing the distribution of the normalized additive concentration of the switching layer in the second embodiment. FIG. 14 shows the distribution of normalized additive concentration in the film thickness direction. The film thickness direction is the first direction.

The first concentration, which is a normalized additive concentration of the high concentration region 41, is higher than a second concentration, which is a normalized additive concentration of the low concentration region 43.

The first concentration C1 of the first contact portion 41x of the high concentration region 41 is, for example, equal to or more than 20% and equal to or less than 99%. The first concentration C1 is preferably equal to or more than 30%. The second concentration C2 of the third contact portion 43x of the low concentration region 43 is, for example, equal to or more than 0.5% and less than 30%.

The difference between the first concentration (C1 in FIG. 14) of the first contact portion 41x of the high concentration region 41 and the second concentration (C2 in FIG. 14) of the third contact portion 43x of the low concentration region 43 is, for example, equal to or more than 20% and equal to or less than 70%.

The distance (d1 in FIG. 14) in the first direction from the lower electrode 10 to a first position (P1 in FIG. 14) where the normalized additive concentration is 30% is, for example, equal to or more than 0.1 nm and equal to or less than 4 nm. In addition, the distance (d2 in FIG. 14) from the intermediate electrode 30 to the first position P1 in the first direction is, for example, equal to or more than 4 nm and equal to or less than 24 nm.

The normalized additive concentration of the switching layer 40 monotonically increases from the lower electrode 10 to the intermediate electrode 30, for example, as indicated by the solid line in FIG. 14.

Next, the function and effect of the memory device according to the second embodiment will be described.

FIG. 6 is a schematic cross-sectional view of a memory cell in the memory device according to the comparative example. FIG. 7 is a diagram showing the distribution of the normalized additive concentration of the switching layer in the comparative example. FIGS. 6 and 7 are diagrams corresponding to FIGS. 13 and 14 in the second embodiment, respectively.

The memory cell MC in the memory device according to the comparative example is different from the memory cell MC in the memory device according to the second embodiment in that the normalized additive concentration of the switching layer 40 is constant in the film thickness direction, as shown by the solid line X or the dotted line Y in FIG. 7.

In addition, the switching element in the memory device according to the comparative example has a problem that the half-select leakage current increases particularly when the normalized additive concentration of the switching layer 40 is relatively high as shown by the solid line X in FIG. 7.

In the memory device according to the second embodiment, the switching layer 40 includes a high concentration region 41 and a low concentration region 43. The first concentration, which is a normalized additive concentration of the high concentration region 41, is higher than the second concentration, which is a normalized additive concentration of the low concentration region 43. In other words, a concentration gradient is provided in the additive concentration of the switching layer 40. In addition, the second concentration C2 of the third contact portion 43x of the low concentration region 43 is less than 30%.

By providing a concentration gradient in the additive concentration of the switching layer 40 to set the second concentration C2 of the third contact portion 43x of the low concentration region 43 to less than 30%, the half-select leakage current of the switching element in the second embodiment is reduced. This is believed to be because the current flowing through the switching layer 40 is suppressed by providing the low concentration region 43, which has a low additive concentration and high electrical resistance.

From the viewpoint of reducing the half-select leakage current of the switching element, the distance d1 in the first direction from the lower electrode 10 to the first position P1 where the normalized additive concentration is 30% is preferably equal to or more than 0.5 nm, more preferably equal to or more than 1 nm, and even more preferably equal to or more than 2 nm.

From the viewpoint of realizing a high on-current of the switching element, it is preferable that the distance d1 in the first direction from the lower electrode 10 to the first position P1 where the normalized additive concentration is 30% is equal to or less than 4 nm.

From the viewpoint of realizing a high on-current of the switching element, the difference between the first concentration C1 of the first contact portion 41x of the high concentration region 41 and the second concentration C2 of the third contact portion 43x of the low concentration region 43 is preferably equal to or more than 20%, more preferably equal to or more than 30%.

From the viewpoint of realizing a high on-current of the switching element, the first concentration C1 of the first contact portion 41x of the high concentration region 41 is preferably equal to or more than 50%, more preferably equal to or more than 60%, and even more preferably equal to or more than 70%.

According to the second embodiment, since the half-select leakage current of the switching element is reduced, it is possible to realize a switching element with excellent characteristics. Therefore, it is possible to realize a memory device having a switching element with excellent characteristics.

### Modification Example

A memory device according to a modification example of the second embodiment is different from the memory device according to the second embodiment in that the second region is provided between the first region and the third conductive layer.

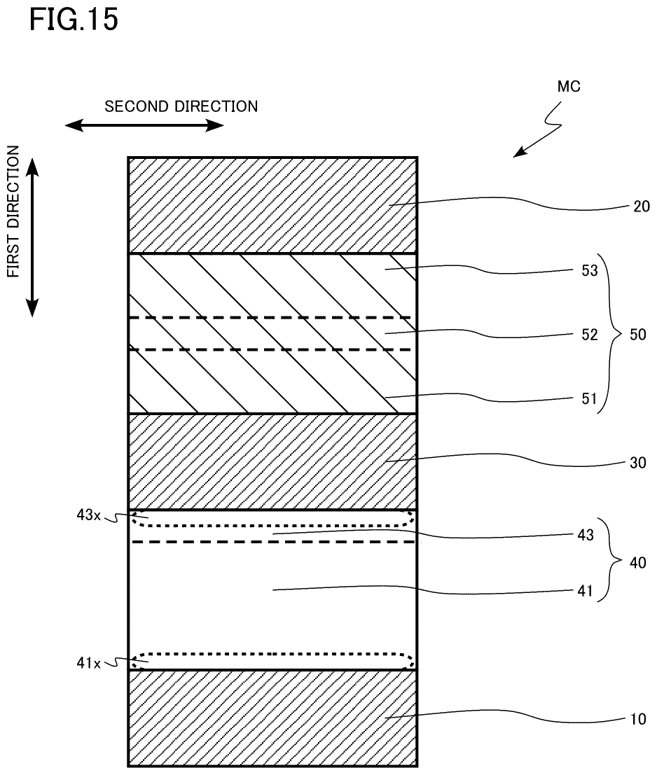

FIG. 15 is a schematic cross-sectional view of a memory cell in the memory device according to the modification example of the second embodiment. FIG. 15 is a diagram corresponding to FIG. 13 in the second embodiment.

The switching layer 40 includes a high concentration region 41 and a low concentration region 43. The low concentration region 43 is provided between the high concentration region 41 and the intermediate electrode 30.

The high concentration region 41 is in contact with, for example, the lower electrode 10. A portion of the high concentration region 41 in contact with the lower electrode 10 is the first contact portion 41x.

The low concentration region 43 is in contact with, for example, the intermediate electrode 30. A portion of the low concentration region 43 in contact with the intermediate electrode 30 is the third contact portion 43x.

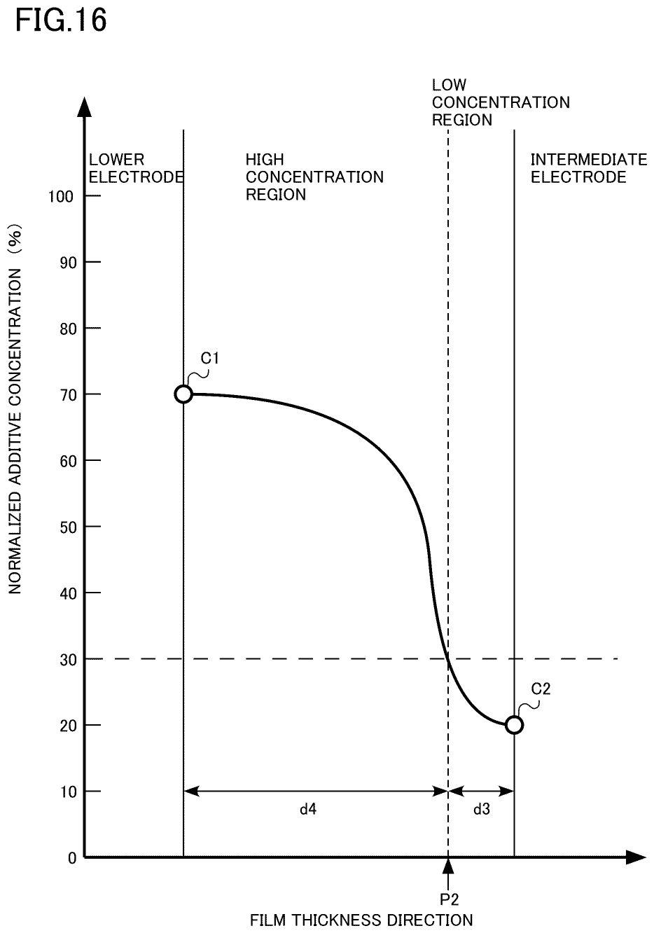

FIG. 16 is a diagram showing the distribution of the normalized additive concentration of the switching layer in the modification example of the second embodiment. FIG. 16 shows the distribution of normalized additive concentration in the film thickness direction. The film thickness direction is the first direction. FIG. 16 is a diagram corresponding to FIG. 14 in the second embodiment.

The first concentration, which is a normalized additive concentration of the high concentration region 41, is higher than the second concentration, which is a normalized additive concentration of the low concentration region 43.

The first concentration C1 of the first contact portion 41x of the high concentration region 41 is, for example, equal to or more than 20% and equal to or less than 99%. The first concentration C1 is preferably equal to or more than 30%. The second concentration C2 of the third contact portion 43x of the low concentration region 43 is, for example, equal to or more than 0.5% and less than 30%.

The difference between the first concentration (C1 in FIG. 16) of the first contact portion 41x of the high concentration region 41 and the second concentration (C2 in FIG. 16) of the third contact portion 43x of the low concentration region 43 is, for example, equal to or more than 20% and equal to or less than 70%.

The distance (d3 in FIG. 16) in the first direction from the intermediate electrode 30 to a second position (P2 in FIG. 16) where the normalized additive concentration is 30% is, for example, equal to or more than 0.1 nm and equal to or less than 4 nm. In addition, the distance (d4 in FIG. 16) from the lower electrode 10 to the second position P2 in the first direction is, for example, equal to or more than 4 nm and equal to or less than 24 nm.

The normalized additive concentration of the switching layer 40 monotonically decreases from the lower electrode 10 to the intermediate electrode 30 as indicated by the solid line in FIG. 16, for example.

From the viewpoint of reducing the half-select leakage current of the switching element, the distance d3 in the first direction from the intermediate electrode 30 to the second position P2 where the normalized additive concentration is 30% is preferably equal to or more than 0.5 nm, more preferably equal to or more than 1 nm, and even more preferably equal to or more than 2 nm.

From the viewpoint of realizing a high on-current of the switching element, it is preferable that the distance d3 in the first direction from the intermediate electrode 30 to the second position P2 where the normalized additive concentration is 30% is equal to or less than 4 nm.

From the viewpoint of realizing a high on-current of the switching element, the difference between the first concentration C1 of the first contact portion 41x of the high concentration region 41 and the second concentration C2 of the third contact portion 43x of the low concentration region 43 is preferably equal to or more than 20%, more preferably equal to or more than 30%.

From the viewpoint of realizing a high on-current of the switching element, the first concentration C1 of the first contact portion 41x of the high concentration region 41 is preferably equal to or more than 50%, more preferably equal to or more than 60%, and even more preferably equal to or more than 70%.

As described above, according to the modification example of the second embodiment, it is possible to realize a switching element with excellent characteristics as in the second embodiment. Therefore, it is possible to realize a memory device having a switching element with excellent characteristics.

According to the second embodiment and its modification examples, since the half-select leakage current of the switching element is reduced, it is possible to realize a switching element with excellent characteristics. Therefore, according to the second embodiment and its modification examples, it is possible to realize a memory device having a switching element with excellent characteristics.

### Third Embodiment

A memory device according to a third embodiment is different from the memory device according to the first embodiment in that the switching layer further includes a third region, a first region is provided between the third region and the second region, and the third concentration, which is a concentration obtained by dividing the sum of the atomic concentration of the second element and the atomic concentration of the third element in the third region by the summed concentration, is lower than the second concentration. Hereinafter, the description of a part of the content overlapping the first embodiment may be omitted.

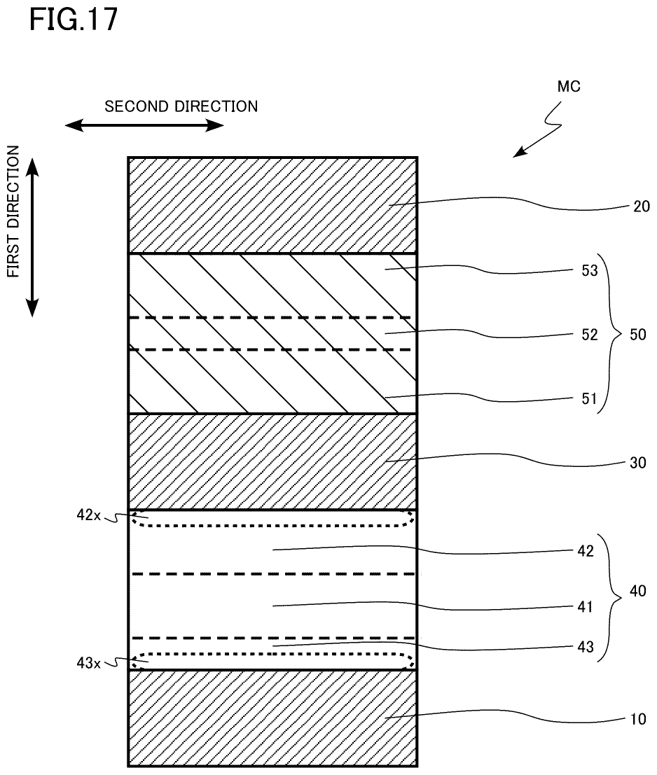

FIG. 17 is a schematic cross-sectional view of a memory cell in the memory device according to the third embodiment. FIG. 17 is a diagram corresponding to FIG. 2 in the first embodiment.

As shown in FIG. 17, the memory cell MC includes a lower electrode 10, an upper electrode 20, an intermediate electrode 30, a switching layer 40, and a variable resistance layer 50. The switching layer 40 includes a high concentration region 41, a medium concentration region 42, and a low concentration region 43. The medium concentration region 42 includes a second contact portion 42x. The low concentration region 43 includes a third contact portion 43x.

The lower electrode 10 is an example of the first conductive layer. The upper electrode 20 is an example of the second conductive layer. The intermediate electrode 30 is an example of the third conductive layer. The high concentration region 41 is an example of the first region. The medium concentration region 42 is an example of the second region. The low concentration region 43 is an example of the third region. The second contact portion 42x is an example of the fourth portion. The third contact portion 43x is an example of the third portion.

The switching layer 40 includes the high concentration region 41, the medium concentration region 42, and the low concentration region 43. The high concentration region 41 is provided between the low concentration region 43 and the medium concentration region 42. The low concentration region 43 is provided between the high concentration region 41 and the lower electrode 10. The medium concentration region 42 is provided between the high concentration region 41 and the intermediate electrode 30.

The medium concentration region 42 is in contact with, for example, the intermediate electrode 30. A portion of the medium concentration region 42 in contact with the intermediate electrode 30 is the second contact portion 42x.

The low concentration region 43 is in contact with, for example, the lower electrode 10. A portion of the low concentration region 43 in contact with the lower electrode 10 is the third contact portion 43x.

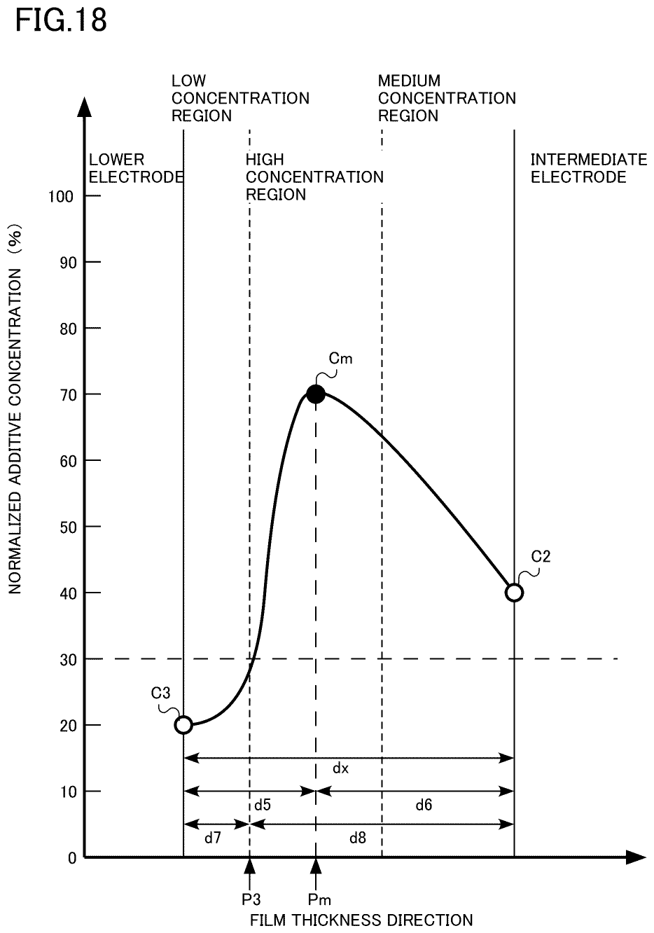

FIG. 18 is a diagram showing the distribution of the normalized additive concentration of the switching layer in the third embodiment. FIG. 18 shows the distribution of normalized additive concentration in the film thickness direction. The film thickness direction is the first direction.

The first concentration, which is a normalized additive concentration of the high concentration region 41, is higher than the second concentration, which is a normalized additive concentration of the medium concentration region 42. The third concentration, which is a normalized additive concentration of the low concentration region 43, is lower than the second concentration, which is a normalized additive concentration of the medium concentration region 42, and the first concentration, which is a normalized additive concentration of the high concentration region 41.

As shown in FIG. 18, the distribution of normalized additive concentration in the first direction in the switching layer 40 has a maximum value (Cm in FIG. 18) at the position Pm of the high concentration region 41. The distance (d5 in FIG. 18) from the lower electrode 10 to the position Pm is smaller than, for example, the distance (d6 in FIG. 18) from the intermediate electrode 30 to the position Pm.

The distance d6 from the intermediate electrode 30 to the position Pm is greater than, for example, one-fifth of the distance dx between the lower electrode 10 and the intermediate electrode 30.

The maximum value Cm of the high concentration region 41 is, for example, equal to or more than 40% and equal to or less than 99%. The second concentration C2 of the second contact portion 42x of the medium concentration region 42 is, for example, equal to or more than 30% and equal to or less than 70%. The third concentration C3 of the third contact portion 43x of the low concentration region 43 is, for example, equal to or more than 0.5% and less than 30%.

The difference between the maximum value Cm of the high concentration region 41 and the second concentration C2 of the second contact portion 42x of the medium concentration region 42 is, for example, equal to or more than 10% and equal to or less than 70%.

The distance (d7 in FIG. 18) in the first direction from the lower electrode 10 to the third position (P3 in FIG. 18) where the normalized additive concentration is 30% is, for example, equal to or more than 0.1 nm and equal to or less than 4 nm. In addition, the distance (d8 in FIG. 18) from the intermediate electrode 30 to the third position P3 in the first direction is, for example, equal to or more than 4 nm and equal to or less than 24 nm.

Next, the function and effect of the memory device according to the third embodiment will be described.

FIG. 6 is a schematic cross-sectional view of a memory cell in the memory device according to the comparative example. FIG. 7 is a diagram showing the distribution of the normalized additive concentration of the switching layer in the comparative example. FIGS. 6 and 7 are diagrams corresponding to FIGS. 17 and 18 in the third embodiment, respectively.

The memory cell MC in the memory device according to the comparative example is different from the memory cell MC in the memory device according to the third embodiment in that the normalized additive concentration of the switching layer 40 is constant in the film thickness direction, as shown by the solid line X or the dotted line Y in FIG. 7.

The memory device according to the comparative example has a problem that the endurance tolerance of the switching element is low, for example. In addition, the memory device according to the comparative example has a problem that the half-select leakage current of the switching element increases particularly when the normalized additive concentration of the switching layer 40 is relatively high as shown by the solid line X in FIG. 7.

In the memory device according to the third embodiment, the switching layer 40 includes a high concentration region 41, a medium concentration region 42, and a low concentration region 43. The first concentration, which is a normalized additive concentration of the high concentration region 41, is higher than the second concentration, which is a normalized additive concentration of the medium concentration region 42. In other words, a concentration gradient is provided in the additive concentration of the switching layer 40. In addition, the third concentration C3 of the third contact portion 43x of the low concentration region 43 is less than 30%.

By providing a concentration gradient in the additive concentration of the switching layer 40, the endurance tolerance of the switching element is increased, as in the first embodiment. In addition, by providing the low concentration region 43 in the switching layer 40 to set the third concentration C3 of the third contact portion 43x of the low concentration region 43 to less than 30%, the half-select leakage current of the switching element is reduced, as in the second embodiment.

From the viewpoint of suppressing the movement of the second element and the third element to realize the high endurance tolerance, the difference between the maximum value Cm of the high concentration region 41 and the second concentration C2 of the second contact portion 42x of the medium concentration region 42 is preferably equal to or more than 10%, more preferably equal to or more than 20%, and even more preferably equal to or more than 30%.

From the viewpoint of reducing the half-select leakage current of the switching element, the distance d7 in the first direction from the lower electrode 10 to the third position P3 where the normalized additive concentration is 30% is preferably equal to or more than 0.5 nm, more preferably equal to or more than 1 nm, and even more preferably equal to or more than 2 nm.

From the viewpoint of realizing a high on-current of the switching element to reduce the half-select leakage current of the switching element, it is preferable that the distance d5 from the lower electrode 10 to the position Pm where the maximum value Cm is obtained is smaller than the distance d6 from the intermediate electrode 30 to the position Pm.

From the viewpoint of realizing a high on-current of the switching element, it is preferable that the distance d7 in the first direction from the lower electrode 10 to the third position P3 where the normalized additive concentration is 30% is equal to or less than 4 nm.

From the viewpoint of realizing a high on-current of the switching element, the maximum value Cm of the high concentration region 41 is preferably equal to or more than 50%, more preferably equal to or more than 60%, and even more preferably equal to or more than 70%.

According to the third embodiment, it is possible to realize a switching element with excellent characteristics, including high endurance tolerance and small half-select leakage current. Therefore, it is possible to realize a memory device having a switching element with excellent characteristics.

### Modification Example

A memory device according to a modification example of the third embodiment is different from the memory device according to the third embodiment in that the third region is provided between the first region and the third conductive layer.

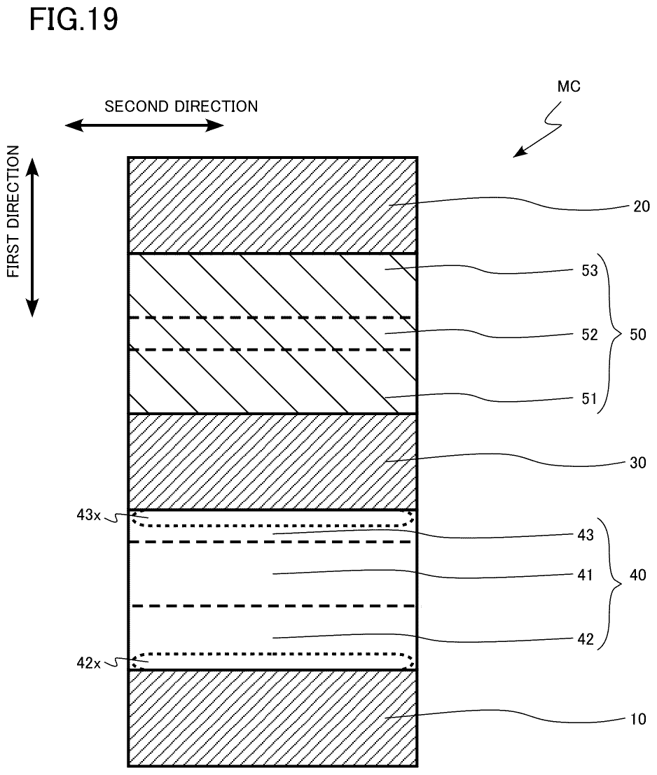

FIG. 19 is a schematic cross-sectional view of a memory cell in the memory device according to the modification example of the third embodiment. FIG. 19 is a diagram corresponding to FIG. 17 in the third embodiment.

The switching layer 40 includes a high concentration region 41, a medium concentration region 42, and a low concentration region 43. The medium concentration region 42 includes a second contact portion 42x. The low concentration region 43 includes a third contact portion 43x.

The high concentration region 41 is an example of the first region. The medium concentration region 42 is an example of the second region. The low concentration region 43 is an example of the third region. The second contact portion 42x is an example of the fourth portion. The third contact portion 43x is an example of the third portion.

The switching layer 40 includes a high concentration region 41, a medium concentration region 42, and a low concentration region 43. The high concentration region 41 is provided between the low concentration region 43 and the medium concentration region 42. The low concentration region 43 is provided between the high concentration region 41 and the intermediate electrode 30. The medium concentration region 42 is provided between the high concentration region 41 and the lower electrode 10.

The medium concentration region 42 is in contact with, for example, the lower electrode 10. A portion of the medium concentration region 42 in contact with the intermediate electrode 30 is the second contact portion 42x.

The low concentration region 43 is in contact with, for example, the intermediate electrode 30. A portion of the low concentration region 43 in contact with the intermediate electrode 30 is the third contact portion 43x.

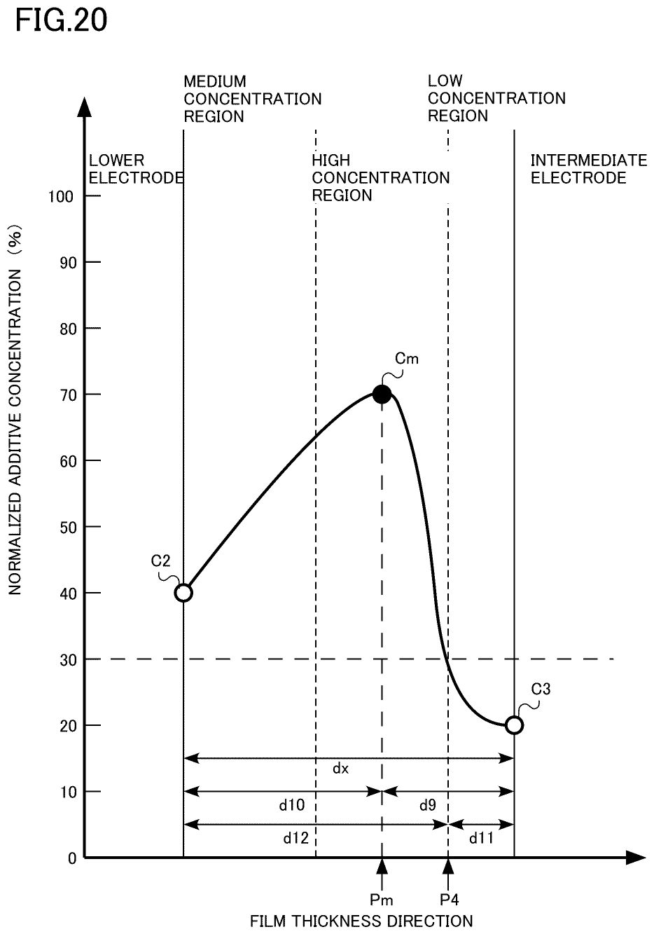

FIG. 20 is a diagram showing the distribution of the normalized additive concentration of the switching layer in the modification example of the third embodiment. FIG. 20 shows the distribution of normalized additive concentration in the film thickness direction. The film thickness direction is the first direction. FIG. 20 is a diagram corresponding to FIG. 18 in the third embodiment.

The first concentration, which is a normalized additive concentration of the high concentration region 41, is higher than the second concentration, which is a normalized additive concentration of the medium concentration region 42. The third concentration, which is a normalized additive concentration of the low concentration region 43, is lower than the second concentration, which is a normalized additive concentration of the medium concentration region 42, and the first concentration, which is a normalized additive concentration of the high concentration region 41.

As shown in FIG. 20, the distribution of normalized additive concentration in the first direction in the switching layer 40 has a maximum value (Cm in FIG. 20) at a position Pm of the high concentration region 41. The distance (d9 in FIG. 20) from the intermediate electrode 30 to the position Pm is smaller than, for example, the distance (d10 in FIG. 20) from the lower electrode 10 to the position Pm.

The distance d9 from the intermediate electrode 30 to the position Pm is greater than, for example, one-fifth of the distance (dx in FIG. 20) between the lower electrode 10 and the intermediate electrode 30. The distance d10 from the lower electrode 10 to the position Pm is greater than, for example, one-fifth of the distance dx between the lower electrode 10 and the intermediate electrode 30.

The maximum value Cm of the high concentration region 41 is, for example, equal to or more than 40% and equal to or less than 99%. The second concentration C2 of the second contact portion 42x of the medium concentration region 42 is, for example, equal to or more than 30% and equal to or less than 70%. The third concentration C3 of the third contact portion 43x of the low concentration region 43 is, for example, equal to or more than 0.5% and less than 30%.

The difference between the maximum value Cm of the high concentration region 41 and the second concentration C2 of the second contact portion 42x of the medium concentration region 42 is, for example, equal to or more than 10% and equal to or less than 70%.

The distance (d11 in FIG. 20) in the first direction from the intermediate electrode 30 to the fourth position (P4 in FIG. 20) where the normalized additive concentration is 30% is, for example, equal to or more than 0.1 nm and equal to or less than 4 nm. In addition, the distance (d12 in FIG. 20) from the lower electrode 10 to the fourth position P4 in the first direction is, for example, equal to or more than 4 nm and equal to or less than 24 nm.

From the viewpoint of suppressing the movement of the second element and the third element to realize high endurance tolerance of the switching element, the difference between the maximum value Cm of the high concentration region 41 and the second concentration C2 of the second contact portion 42x of the medium concentration region 42 is preferably equal to or more than 10%, more preferably equal to or more than 20%, and even more preferably equal to or more than 30%.

From the viewpoint of reducing the half-select leakage current of the switching element, the distance d11 in the first direction from the intermediate electrode 30 to the fourth position P4 where the normalized additive concentration is 30% is preferably equal to or more than 0.5 nm, more preferably equal to or more than 1 nm, and even more preferably equal to or more than 2 nm.

From the viewpoint of reducing the half-select leakage current of the switching element, it is preferable that the distance d9 from the intermediate electrode 30 to the position Pm where the maximum value Cm is obtained is smaller than the distance d10 from the lower electrode 10 to the position Pm.

From the viewpoint of realizing a high on-current of the switching element, it is preferable that the distance d11 in the first direction from the intermediate electrode 30 to the fourth position P4 where the normalized additive concentration is 30% is equal to or less than 4 nm.

From the viewpoint of realizing a high on-current of the switching element, the maximum value Cm of the high concentration region 41 is preferably equal to or more than 50%, more preferably equal to or more than 60%, and even more preferably equal to or more than 70%.

As described above, according to the modification example of the third embodiment, it is possible to realize a switching element with excellent characteristics as in the third embodiment. Therefore, it is possible to realize a memory device having a switching element with excellent characteristics.

According to the third embodiment and its modification examples, it is possible to realize a switching element with excellent characteristics, including high endurance tolerance and small half-select leakage current. Therefore, according to the third embodiment and its modification examples, it is possible to realize a memory device having a switching element with excellent characteristics.

### Fourth Embodiment

A memory device according to a fourth embodiment is different from the memory device according to the first embodiment in that the memory device according to the fourth embodiment is a resistive random access memory (ReRAM). Hereinafter, the description of a part of the content overlapping the first embodiment will be omitted.

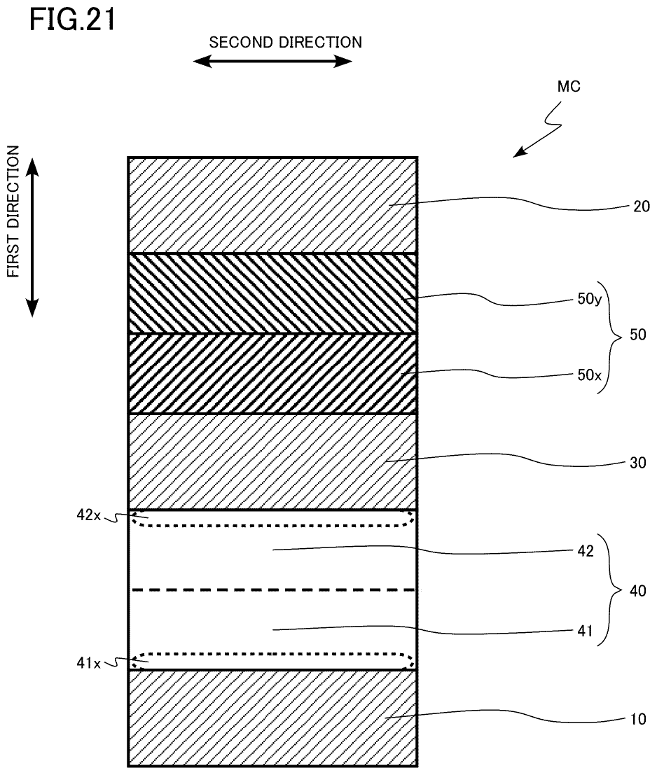

FIG. 21 is a schematic cross-sectional view of a memory cell in the memory device according to the fourth embodiment. FIG. 21 shows a cross section of one memory cell MC indicated by, for example, a dotted circle in the memory cell array 100 of FIG. 1.

As shown in FIG. 21, the memory cell MC includes a lower electrode 10, an upper electrode 20, an intermediate electrode 30, a switching layer 40, and a variable resistance layer 50. The switching layer 40 includes a high concentration region 41 and a medium concentration region 42. The high concentration region 41 includes a first contact portion 41x. The medium concentration region 42 includes a second contact portion 42x.

The lower electrode 10 is an example of the first conductive layer. The upper electrode 20 is an example of the second conductive layer. The intermediate electrode 30 is an example of the third conductive layer. The high concentration region 41 is an example of the first region. The medium concentration region 42 is an example of the second region. The first contact portion 41x is an example of the first portion. The second contact portion 42x is an example of the second portion.

The lower electrode 10, the switching layer 40, and the intermediate electrode 30 form a switching element of the memory cell MC. The intermediate electrode 30, the variable resistance layer 50, and the upper electrode 20 form a variable resistance element of the memory cell MC.

The configuration of the switching layer 40 is similar to that in the memory device according to the first embodiment.

The variable resistance layer 50 includes the high resistance layer 50x and the low resistance layer 50y.

The high resistance layer 50x is, for example, a metal oxide. The high resistance layer 50x is, for example, an aluminum oxide, a hafnium oxide, a zirconium oxide, a tantalum oxide, or a niobium oxide.

The low resistance layer 50y is, for example, a metal oxide. The low resistance layer 50y is, for example, a titanium oxide, a niobium oxide, a tantalum oxide, or a tungsten oxide.

The variable resistance layer 50 has a function of storing data by resistance change. The variable resistance layer 50 has, for example, a characteristic that the electrical resistance changes by the application of a predetermined voltage.

By applying a voltage to the variable resistance layer 50, the variable resistance layer 50 changes from a high resistance state to a low resistance state or from a low resistance state to a high resistance state. By applying a voltage to the variable resistance layer 50, oxygen ions move between the high resistance layer 50x and the low resistance layer 50y, so that the amount of oxygen deficiency (the amount of oxygen vacancies) in the low resistance layer 50y changes. The electrical conductivity of the variable resistance layer 50 changes according to the amount of oxygen deficiency in the low resistance layer 50y. The low resistance layer 50y is a so-called vacancy modulated conductive oxide.

For example, the high resistance state is defined as data “1”, and the low resistance state is defined as data “0”. The memory cell MC can store 1-bit data of “0” and “1”.

As described above, according to the memory device according to the fourth embodiment, it is possible to realize a switching element with excellent characteristics as in the first embodiment. Therefore, according to the fourth embodiment, it is possible to realize a memory device having a switching element with excellent characteristics.

### Fifth Embodiment

A memory device according to a fifth embodiment includes a memory cell including a first conductive layer, a second conductive layer, and a memory layer provided between the first conductive layer and the second conductive layer. The memory layer contains an oxide, a nitride, or an oxynitride of at least one first element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg), at least one second element different from the at least one first element and selected from a group consisting of aluminum (Al), zinc (Zn), tin (Sn), gallium (Ga), and indium (In), and at least one third element selected from a group consisting of tellurium (Te), sulfur(S), selenium (Se), and antimony (Sb). The memory layer includes a first region and a second region, and the second region is provided either between the first region and the first conductive layer or between the first region and the second conductive layer. Assuming that the sum of the atomic concentration of the first element, the atomic concentration of the second element, the atomic concentration of the third element, the atomic concentration of oxygen (O), and the atomic concentration of nitrogen (N) is a summed concentration, the first concentration, which is a concentration obtained by dividing the sum of the atomic concentration of the second element and the atomic concentration of the third element in the first region by the summed concentration, is higher than the second concentration, which is a concentration obtained by dividing the sum of the atomic concentration of the second element and the atomic concentration of the third element in the second region by the summed concentration.

In addition, the memory device according to the fifth embodiment further includes a plurality of first wirings and a plurality of second wirings crossing the plurality of first wirings. In addition, the memory cell is provided in a region where one of the plurality of first wirings and one of the plurality of second wirings cross each other.

The memory device according to the fifth embodiment is different from the memory device according to the first embodiment in that the memory cell does not include a third conductive layer and a variable resistance layer and includes a structure similar to the switching layer in the first embodiment as a memory layer. Hereinafter, the description of a part of the content overlapping the first embodiment will be omitted.

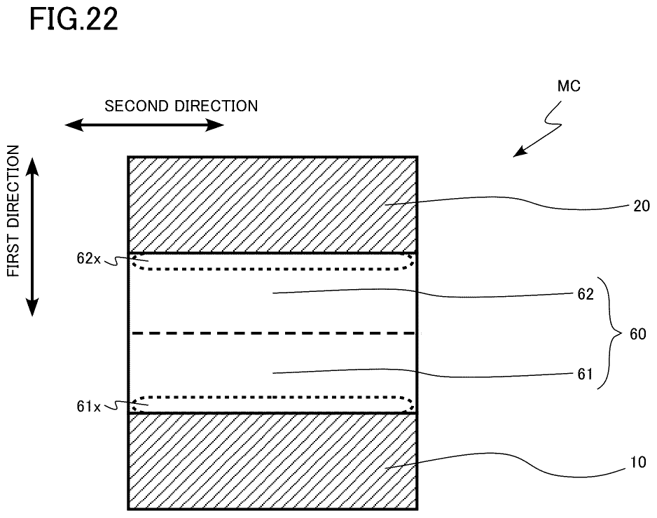

FIG. 22 is a schematic cross-sectional view of a memory cell in the memory device according to the fifth embodiment. FIG. 22 shows a cross section of one memory cell MC indicated by, for example, a dotted circle in the memory cell array 100 of FIG. 1.

As shown in FIG. 22, the memory cell MC includes a lower electrode 10, an upper electrode 20, and a memory layer 60. The memory layer 60 includes a high concentration region 61 and a medium concentration region 62. The high concentration region 61 includes a first contact portion 61x. The medium concentration region 62 includes a second contact portion 62x.

The lower electrode 10 is an example of the first conductive layer. The upper electrode 20 is an example of the second conductive layer. The high concentration region 61 is an example of the first region. The medium concentration region 62 is an example of the second region. The first contact portion 61x is an example of the first portion. The second contact portion 62x is an example of the second portion.

The lower electrode 10, the memory layer 60, and the upper electrode 20 form a memory element of the memory cell MC. The memory element of the memory cell MC has a switching function and an information storage function.

The memory layer 60 has a configuration similar to that of the switching layer 40 in the first embodiment. The high concentration region 61 and the medium concentration region 62 of the memory layer 60 have the same configurations as the high concentration region 41 and the medium concentration region 42 of the switching layer 40 in the first embodiment, respectively.

The memory layer 60 is provided between the lower electrode 10 and the upper electrode 20. The memory layer 60 is in contact with, for example, the lower electrode 10 and the upper electrode 20. The intermediate electrode 30 in the first embodiment corresponds to the upper electrode 20 in the fifth embodiment. The intermediate electrode 30 in the first embodiment realizes a function similar to that of the upper electrode 20 in the fifth embodiment. Therefore, in the fifth embodiment, the third conductive layer in the first embodiment can be read as the second conductive layer.

The memory layer 60 has a nonlinear current-voltage characteristic that a current increases abruptly at a specific threshold voltage. In addition, the memory layer 60 has a characteristic that the threshold voltage changes by the application of a predetermined voltage. The memory layer 60 has a characteristic that the electrical resistance changes by the application of a predetermined voltage. In the fifth embodiment, the high resistance state is a state in which the resistance of the memory layer 60 is relatively high at the read voltage. In addition, in the fifth embodiment, the low resistance state is a state in which the resistance of the memory layer 60 is relatively low at the read voltage.

The memory layer 60 has a function of suppressing an increase in half-select leakage current flowing through the half-selected cell. In addition, the memory layer 60 has a function of storing data by resistance change. The memory layer 60 is a single layer, and realizes the function of the switching layer 40 and the function of the variable resistance layer 50 in the first embodiment.

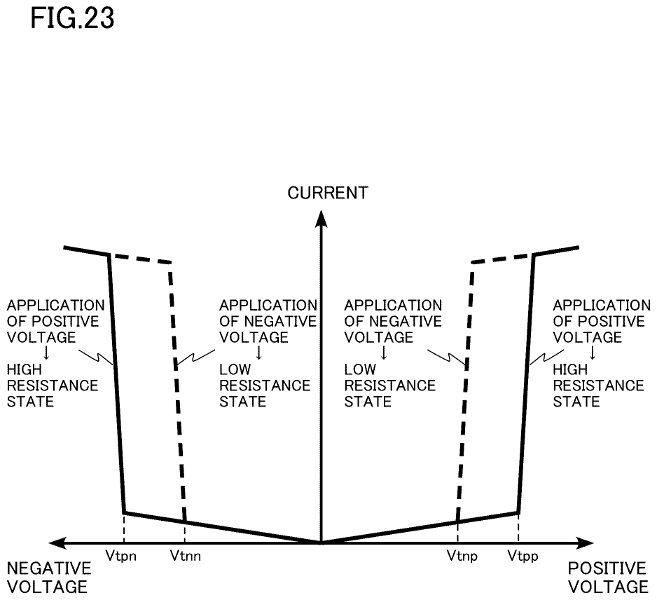

FIG. 23 is an explanatory diagram of the current-voltage characteristics of the memory element in the fifth embodiment. The horizontal axis indicates a voltage applied to the memory element, and the vertical axis indicates a current flowing through the memory element. In FIG. 23, the horizontal axis indicates a voltage applied to the upper electrode 20 with the electric potential of the lower electrode 10 as a reference. FIG. 23 shows the current-voltage characteristics of the memory layer 60 in the fifth embodiment. FIG. 23 shows the current-voltage characteristics of the memory cell MC in the fifth embodiment.

The memory element in the fifth embodiment shows different current-voltage characteristics when a predetermined positive voltage is applied to the upper electrode 20 and when a predetermined negative voltage is applied to the upper electrode 20. In FIG. 23, the solid line indicates the current-voltage characteristics when a predetermined positive voltage is applied to the upper electrode 20, and the dotted line indicates the current-voltage characteristics when a predetermined negative voltage is applied to the upper electrode 20.

When a predetermined positive voltage is applied to the upper electrode 20, the current increases abruptly at a first positive voltage side threshold voltage Vtpp on the positive voltage side. In addition, when a predetermined positive voltage is applied to the upper electrode 20, the current increases abruptly at a first negative voltage side threshold voltage Vtpn on the negative voltage side.

On the other hand, when a predetermined negative voltage is applied to the upper electrode 20, the current increases abruptly at a second positive voltage side threshold voltage Vtnp on the positive voltage side. In addition, when a predetermined negative voltage is applied to the upper electrode 20, the current increases abruptly at a second negative voltage side threshold voltage Vtnn on the negative voltage side.

The first positive voltage side threshold voltage Vtpp is higher than the second positive voltage side threshold voltage Vtnp. In addition, the first negative voltage side threshold voltage Vtpn is lower than the second negative voltage side threshold voltage Vtnn.

The memory element in the fifth embodiment can have a high resistance state and a low resistance state on both the positive voltage side and the negative voltage side. When a predetermined positive voltage is applied to the upper electrode 20, a high resistance state is realized on both the positive voltage side and the negative voltage side. On the other hand, when a predetermined negative voltage is applied to the upper electrode 20, a low resistance state is realized on both the positive voltage side and the negative voltage side. Hereinafter, the high resistance state will be defined as data “1”, and the low resistance state will be defined as data “0”. The memory cell MC can store 1-bit data of “0” and “1”.

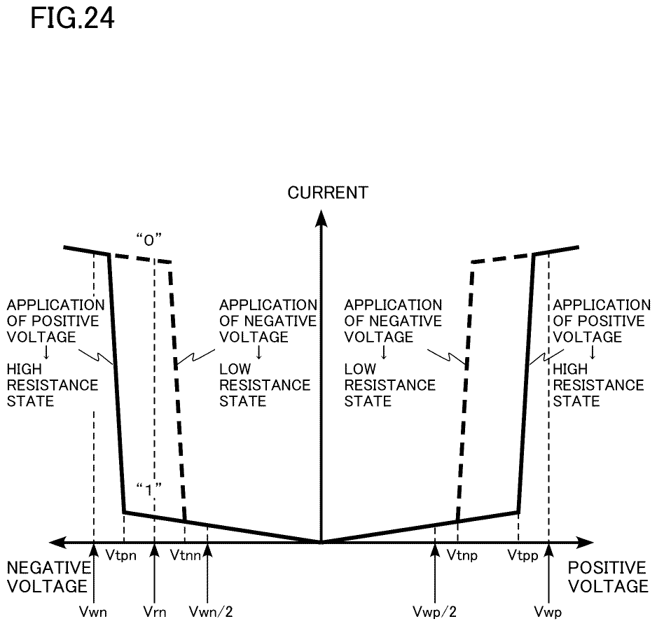

FIG. 24 is an explanatory diagram of a first operation example of the memory operation of the memory device according to the fifth embodiment. FIG. 24 shows a positive side write voltage Vwp, half (Vwp/2) the positive side write voltage Vwp, a negative side write voltage Vwn, half (Vwn/2) the negative side write voltage Vwn, and a negative side read voltage Vrn when performing a memory operation.

In the first operation example, the high resistance state and the low resistance state on the negative voltage side are used for the memory operation. In the first operation example, the negative side read voltage Vrn is used as a read voltage.

When writing data “1” to the selected cell, the positive side write voltage Vwp is applied to the upper electrode 20. The positive side write voltage Vwp is a voltage higher than the first positive voltage side threshold voltage Vtpp. By applying the positive side write voltage Vwp to the upper electrode 20, a high resistance state is realized on the negative voltage side, and data “1” is written to the selected cell.

When writing data “0” to the selected cell, the negative side write voltage Vwn is applied to the upper electrode 20. The negative side write voltage Vwn is a voltage lower than the first negative voltage side threshold voltage Vtpn. By applying the negative side write voltage Vwn to the upper electrode 20, a low resistance state is realized on the negative voltage side, and data “0” is written to the selected cell.

In the first operation example, when writing data “1” to the selected cell, assuming that the data stored in the selected cell is data “0”, a current flows if the positive side write voltage Vwp is higher than the second positive voltage side threshold voltage Vtnp even if the positive side write voltage Vwp is lower than the first positive voltage side threshold voltage Vtpp. For this reason, data “1” may be written. Therefore, for example, by setting the positive side write voltage Vwp to a voltage between the second positive voltage side threshold voltage Vtnp and the first positive voltage side threshold voltage Vtpp, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the second positive voltage side threshold voltage Vtnp. In addition, the voltage Vwn/2 is higher than the second negative voltage side threshold voltage Vtnn.

Therefore, even when the half-selected cell is in the low resistance state, the half-select leakage current flowing through the half-selected cell can be suppressed. As a result, the memory element also functions as a switching element.

When reading data from the selected cell, the negative side read voltage Vrn is applied to the selected cell. The data of the selected cell can be determined by detecting a current change or an electric potential change caused by the difference between a current that flows when data is “1” and a current that flows when data is “0”.

In addition, in the case of the first operation example, regardless of whether the data of the selected cell is data “1” or data “0”, the application of the negative side read voltage Vrn does not destroy the data. In other words, in the case of the first operation example, non-destructive reading is possible regardless of whether the data of the selected cell is data “1” or data “0”.

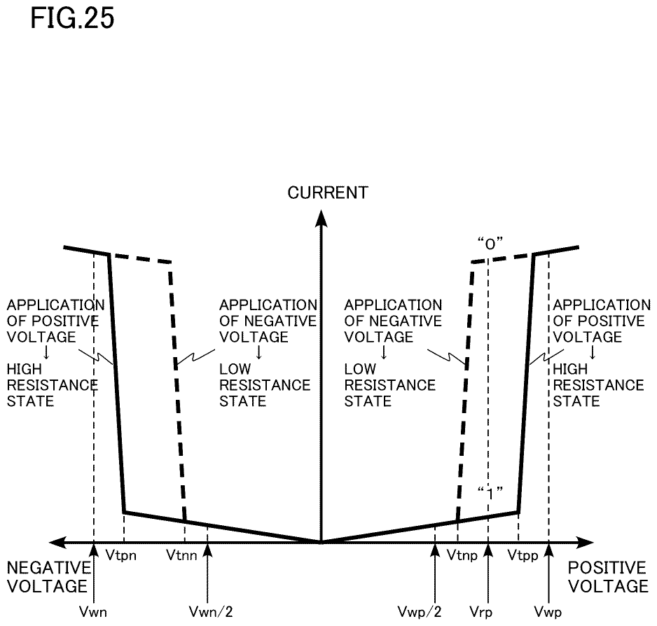

FIG. 25 is an explanatory diagram of a second operation example of the memory operation of the memory device according to the fifth embodiment. FIG. 25 shows a positive side write voltage Vwp, half (Vwp/2) the positive side write voltage Vwp, a negative side write voltage Vwn, half (Vwn/2) the negative side write voltage Vwn, and a positive side read voltage Vrp when performing a memory operation.

In the second operation example, the high resistance state and the low resistance state on the positive voltage side are used for the memory operation. In the second operation example, the positive side read voltage Vrp is used as a read voltage.

When writing data “1” to the selected cell, the positive side write voltage Vwp is applied to the upper electrode 20. The positive side write voltage Vwp is a voltage higher than the first positive voltage side threshold voltage Vtpp. By applying the positive side write voltage Vwp to the upper electrode 20, a high resistance state is realized on the positive voltage side, and data “1” is written to the selected cell.

When writing data “0” to the selected cell, the negative side write voltage Vwn is applied to the upper electrode 20. The negative side write voltage Vwn is a voltage lower than the first negative voltage side threshold voltage Vtpn. By applying the negative side write voltage Vwn to the upper electrode 20, a low resistance state is realized on the positive voltage side, and data “0” is written to the selected cell.

In the second operation example, when writing data “1” to the selected cell, assuming that the data stored in the selected cell is data “0”, a current flows if the positive side write voltage Vwp is higher than the second positive voltage side threshold voltage Vtnp even if the positive side write voltage Vwp is lower than the first positive voltage side threshold voltage Vtpp. For this reason, data “1” may be written. Therefore, for example, by setting the positive side write voltage Vwp to a voltage between the second positive voltage side threshold voltage Vtnp and the first positive voltage side threshold voltage Vtpp, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the second positive voltage side threshold voltage Vtnp. In addition, the voltage Vwn/2 is higher than the second negative voltage side threshold voltage Vtnn.

Therefore, even when the half-selected cell is in the low resistance state, the half-select leakage current flowing through the half-selected cell can be suppressed. As a result, the memory element also functions as a switching element.

When reading data from the selected cell, the positive side read voltage Vrp is applied to the selected cell. The data of the selected cell can be determined by detecting a current change or an electric potential change caused by the difference between a current that flows when data is “1” and a current that flows when data is “0”.

In addition, in the case of the second operation example, when the data of the selected cell is data “1”, the application of the positive side read voltage Vrp does not destroy the data. In other words, in the case of the second operation example, non-destructive reading is possible if the data of the selected cell is data “1”.

On the other hand, when the data of the selected cell is data “0”, the application of the positive side read voltage Vrp higher than the second positive voltage side threshold voltage Vtnp may cause a current to flow. As a result, the data of the selected cell may change to data “1”. In other words, in the case of the second operation example, when the data of the selected cell is data “0”, there is a possibility of destructive reading. Therefore, when the data of the selected cell is data “0”, it may be necessary to rewrite the data “0” in order to maintain the data of the selected cell after reading the data of the selected cell.

### First Modification Example

A memory device according to a first modification example of the fifth embodiment is different from the memory device according to the fifth embodiment in that the current-voltage characteristics of the memory elements are different.

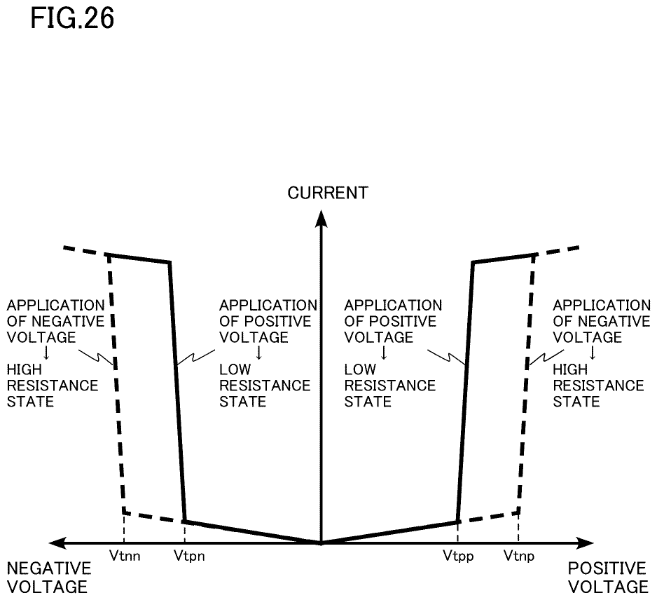

FIG. 26 is an explanatory diagram of the current-voltage characteristics of a memory element in the first modification example of the fifth embodiment. The horizontal axis indicates a voltage applied to the memory element, and the vertical axis indicates a current flowing through the memory element. In FIG. 26, the horizontal axis indicates a voltage applied to the upper electrode 20 with the electric potential of the lower electrode 10 as a reference. FIG. 26 shows the current-voltage characteristics of the memory layer 60 in the first modification example of the fifth embodiment. FIG. 26 shows the current-voltage characteristics of the memory cell MC in the first modification example of the fifth embodiment.

The memory element in the first modification example of the fifth embodiment shows different current-voltage characteristics when a predetermined positive voltage is applied to the upper electrode 20 and when a predetermined negative voltage is applied to the upper electrode 20. In FIG. 26, the solid line indicates the current-voltage characteristics when a predetermined positive voltage is applied to the upper electrode 20, and the dotted line indicates the current-voltage characteristics when a predetermined negative voltage is applied to the upper electrode 20.

When a predetermined positive voltage is applied to the upper electrode 20, the current increases abruptly at a first positive voltage side threshold voltage Vtpp on the positive voltage side. In addition, when a predetermined positive voltage is applied to the upper electrode 20, the current increases abruptly at a first negative voltage side threshold voltage Vtpn on the negative voltage side.

On the other hand, when a predetermined negative voltage is applied to the upper electrode 20, the current increases abruptly at a second positive voltage side threshold voltage Vtnp on the positive voltage side. In addition, when a predetermined negative voltage is applied to the upper electrode 20, the current increases abruptly at a second negative voltage side threshold voltage Vtnn on the negative voltage side.

The first positive voltage side threshold voltage Vtpp is lower than the second positive voltage side threshold voltage Vtnp. In addition, the first negative voltage side threshold voltage Vtpn is higher than the second negative voltage side threshold voltage Vtnn.

The memory element in the first modification example of the fifth embodiment can have a high resistance state and a low resistance state on both the positive voltage side and the negative voltage side. When a predetermined positive voltage is applied to the upper electrode 20, a low resistance state is realized on both the positive voltage side and the negative voltage side. On the other hand, when a predetermined negative voltage is applied to the upper electrode 20, a high resistance state is realized on both the positive voltage side and the negative voltage side. Hereinafter, the high resistance state will be defined as data “1”, and the low resistance state will be defined as data “0”. The memory cell MC can store 1-bit data of “0” and “1”.

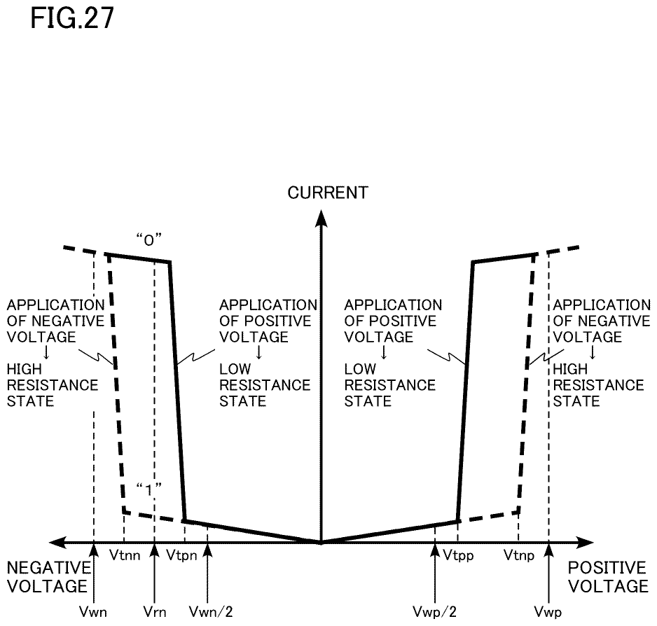

FIG. 27 is an explanatory diagram of a third operation example of the memory operation of the memory device according to the first modification example of the fifth embodiment. FIG. 27 shows a positive side write voltage Vwp, half (Vwp/2) the positive side write voltage Vwp, a negative side write voltage Vwn, half (Vwn/2) the negative side write voltage Vwn, and a negative side read voltage Vrn when performing a memory operation.

In the third operation example, the high resistance state and the low resistance state on the negative voltage side are used for the memory operation. In the third operation example, the negative side read voltage Vrn is used as a read voltage.

When writing data “1” to the selected cell, the negative side write voltage Vwn is applied to the upper electrode 20. The negative side write voltage Vwn is a voltage lower than the second negative voltage side threshold voltage Vtnn. By applying the negative side write voltage Vwn to the upper electrode 20, a high resistance state is realized on the negative voltage side, and data “1” is written to the selected cell.

When writing data “0” to the selected cell, the positive side write voltage Vwp is applied to the upper electrode 20. The positive side write voltage Vwp is a voltage higher than the second positive voltage side threshold voltage Vtnp. By applying the positive side write voltage Vwp to the upper electrode 20, a low resistance state is realized on the negative voltage side, and data “0” is written to the selected cell.

In the third operation example, when writing data “1” to the selected cell, assuming that the data stored in the selected cell is data “0”, a current flows if the negative side write voltage Vwn is lower than the first negative voltage side threshold voltage Vtpn even if the negative side write voltage Vwn is higher than the second negative voltage side threshold voltage Vtnn. For this reason, data “1” may be written. Therefore, for example, by setting the negative side write voltage Vwn to a voltage between the second negative voltage side threshold voltage Vtnn and the first negative voltage side threshold voltage Vtpn, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the first positive voltage side threshold voltage Vtpp. In addition, the voltage Vwn/2 is higher than the first negative voltage side threshold voltage Vtpn.

Therefore, even when the half-selected cell is in the low resistance state, the half-select leakage current flowing through the half-selected cell can be suppressed. As a result, the memory element also functions as a switching element.

When reading data from the selected cell, the negative side read voltage Vrn is applied to the selected cell. The data of the selected cell can be determined by detecting a current change or an electric potential change caused by the difference between a current that flows when data is “1” and a current that flows when data is “0”.

In addition, in the case of the third operation example, when the data of the selected cell is data “1”, the application of the negative side read voltage Vrn does not destroy the data. In other words, in the case of the third operation example, non-destructive reading is possible if the data of the selected cell is data “1”.

On the other hand, when the data of the selected cell is data “0”, the application of the negative side read voltage Vrn lower than the first negative voltage side threshold voltage Vtpn may cause a current to flow. As a result, the data of the selected cell may change to data “1”. In other words, in the case of the third operation example, when the data of the selected cell is data “0”, there is a possibility of destructive reading. Therefore, when the data of the selected cell is data “0”, it may be necessary to rewrite the data “0” in order to maintain the data of the selected cell after reading the data of the selected cell.

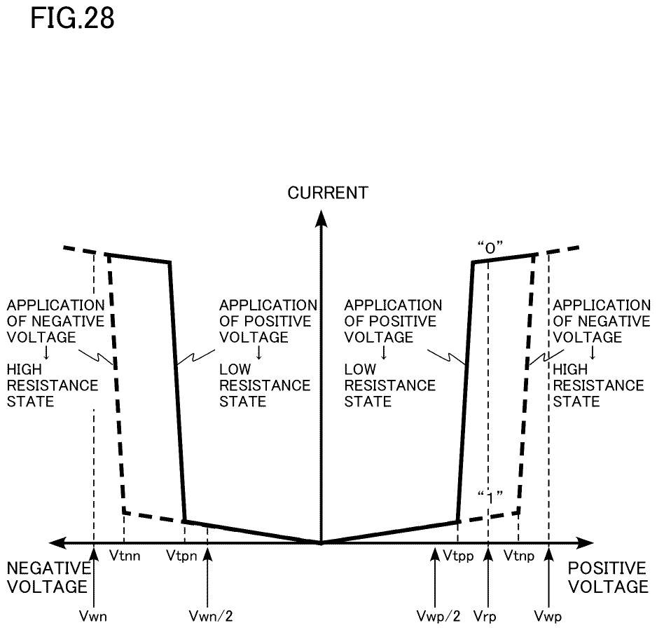

FIG. 28 is an explanatory diagram of a fourth operation example of the memory operation of the memory device according to the first modification example of the fifth embodiment. FIG. 28 shows a positive side write voltage Vwp, half (Vwp/2) the positive side write voltage Vwp, a negative side write voltage Vwn, half (Vwn/2) the negative side write voltage Vwn, and a positive side read voltage Vrp when performing a memory operation.

In the fourth operation example, the high resistance state and the low resistance state on the positive voltage side are used for the memory operation. In the fourth operation example, the positive side read voltage Vrp is used as a read voltage.

When writing data “1” to the selected cell, the negative side write voltage Vwn is applied to the upper electrode 20. The negative side write voltage Vwn is a voltage lower than the second negative voltage side threshold voltage Vtnn. By applying the negative side write voltage Vwn to the upper electrode 20, a high resistance state is realized on the positive voltage side, and data “1” is written to the selected cell.

When writing data “0” to the selected cell, the positive side write voltage Vwp is applied to the upper electrode 20. The positive side write voltage Vwp is a voltage higher than the second positive voltage side threshold voltage Vtnp. By applying the positive side write voltage Vwp to the upper electrode 20, a low resistance state is realized on the positive voltage side, and data “0” is written to the selected cell.

In the fourth operation example, when writing data “1” to the selected cell, assuming that the data stored in the selected cell is data “0”, a current flows if the negative side write voltage Vwn is lower than the first negative voltage side threshold voltage Vtpn even if the negative side write voltage Vwn is higher than the second negative voltage side threshold voltage Vtnn. For this reason, data “1” may be written. Therefore, for example, by setting the negative side write voltage Vwn to a voltage between the second negative voltage side threshold voltage Vtnn and the first negative voltage side threshold voltage Vtpn, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the first positive voltage side threshold voltage Vtpp. In addition, the voltage Vwn/2 is higher than the first negative voltage side threshold voltage Vtpn.

Therefore, even when the half-selected cell is in the low resistance state, the half-select leakage current flowing through the half-selected cell can be suppressed. As a result, the memory element also functions as a switching element.

When reading data from the selected cell, the positive side read voltage Vrp is applied to the selected cell. The data of the selected cell can be determined by detecting a current change or an electric potential change caused by the difference between a current that flows when data is “1” and a current that flows when data is “0”.

In addition, in the case of the fourth operation example, regardless of whether the data of the selected cell is data “1” or data “0”, the application of the positive side read voltage Vrp does not destroy the data. In other words, in the case of the fourth operation example, non-destructive reading is possible regardless of whether the data of the selected cell is data “1” or data “0”.

### Second Modification Example

A memory device according to a second modification example of the fifth embodiment is different from the memory device according to the fifth embodiment in that the current-voltage characteristics of the memory elements are different.

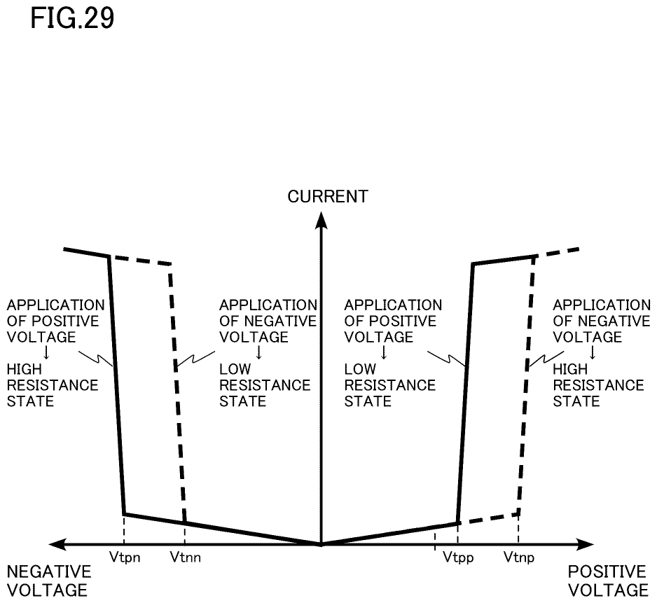

FIG. 29 is an explanatory diagram of the current-voltage characteristics of the memory element in the second modification example of the fifth embodiment. The horizontal axis indicates a voltage applied to the memory element, and the vertical axis indicates a current flowing through the memory element. In FIG. 29, the horizontal axis indicates a voltage applied to the upper electrode 20 with the electric potential of the lower electrode 10 as a reference. FIG. 29 shows the current-voltage characteristics of the memory layer 60 in the second modification example of the fifth embodiment. FIG. 29 shows the current-voltage characteristics of the memory cell MC in the second modification example of the fifth embodiment.

The memory element in the second modification example of the fifth embodiment shows different current-voltage characteristics when a predetermined positive voltage is applied to the upper electrode 20 and when a predetermined negative voltage is applied to the upper electrode 20. In FIG. 29, the solid line indicates the current-voltage characteristics when a predetermined positive voltage is applied to the upper electrode 20, and the dotted line indicates the current-voltage characteristics when a predetermined negative voltage is applied to the upper electrode 20.

When a predetermined positive voltage is applied to the upper electrode 20, the current increases abruptly at a first positive voltage side threshold voltage Vtpp on the positive voltage side. In addition, when a predetermined positive voltage is applied to the upper electrode 20, the current increases abruptly at a first negative voltage side threshold voltage Vtpn on the negative voltage side.

On the other hand, when a predetermined negative voltage is applied to the upper electrode 20, the current increases abruptly at a second positive voltage side threshold voltage Vtnp on the positive voltage side. In addition, when a predetermined negative voltage is applied to the upper electrode 20, the current increases abruptly at a second negative voltage side threshold voltage Vtnn on the negative voltage side.

The first positive voltage side threshold voltage Vtpp is lower than the second positive voltage side threshold voltage Vtnp. In addition, the first negative voltage side threshold voltage Vtpn is lower than the second negative voltage side threshold voltage Vtnn.

The memory element in the second modification example of the fifth embodiment can have a high resistance state and a low resistance state on both the positive voltage side and the negative voltage side. When a predetermined positive voltage is applied to the upper electrode 20, a low resistance state is realized on the positive voltage side and a high resistance state is realized on the negative voltage side. On the other hand, when a predetermined negative voltage is applied to the upper electrode 20, a high resistance state is realized on the positive voltage side and a low resistance state is realized on the negative voltage side. Hereinafter, the high resistance state will be defined as data “1”, and the low resistance state will be defined as data “0”. The memory cell MC can store 1-bit data of “0” and “1”.

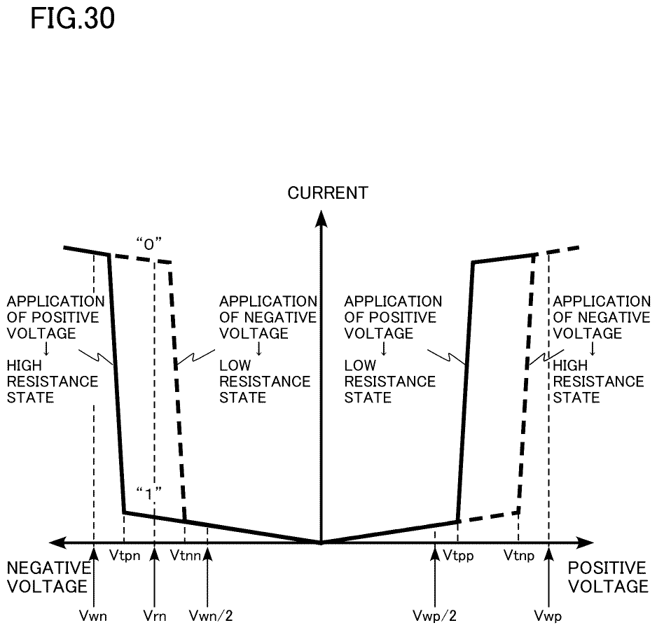

FIG. 30 is an explanatory diagram of a fifth operation example of the memory operation of the memory device according to the second modification example of the fifth embodiment. FIG. 30 shows a positive side write voltage Vwp, half (Vwp/2) the positive side write voltage Vwp, a negative side write voltage Vwn, half (Vwn/2) the negative side write voltage Vwn, and a negative side read voltage Vrn when performing a memory operation.

In the fifth operation example, the high resistance state and the low resistance state on the negative voltage side are used for the memory operation. In the fifth operation example, the negative side read voltage Vrn is used as a read voltage.

When writing data “1” to the selected cell, the positive side write voltage Vwp is applied to the upper electrode 20. The positive side write voltage Vwp is a voltage higher than the second positive voltage side threshold voltage Vtnp. By applying the positive side write voltage Vwp to the upper electrode 20, a high resistance state is realized on the negative voltage side, and data “1” is written to the selected cell.

When writing data “0” to the selected cell, the negative side write voltage Vwn is applied to the upper electrode 20. The negative side write voltage Vwn is a voltage lower than the first negative voltage side threshold voltage Vtpn. By applying the negative side write voltage Vwn to the upper electrode 20, a low resistance state is realized on the negative voltage side, and data “0” is written to the selected cell.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the first positive voltage side threshold voltage Vtpp. In addition, the voltage Vwn/2 is higher than the second negative voltage side threshold voltage Vtnn.

Therefore, even when the half-selected cell is in the low resistance state, the half-select leakage current flowing through the half-selected cell can be suppressed. As a result, the memory element also functions as a switching element.

When reading data from the selected cell, the negative side read voltage Vrn is applied to the selected cell. The data of the selected cell can be determined by detecting a current change or an electric potential change caused by the difference between a current that flows when data is “1” and a current that flows when data is “0”.

In addition, in the case of the fifth operation example, regardless of whether the data of the selected cell is data “1” or data “0”, the application of the negative side read voltage Vrn does not destroy the data. In other words, in the case of the fifth operation example, non-destructive reading is possible regardless of whether the data of the selected cell is data “1” or data “0”.

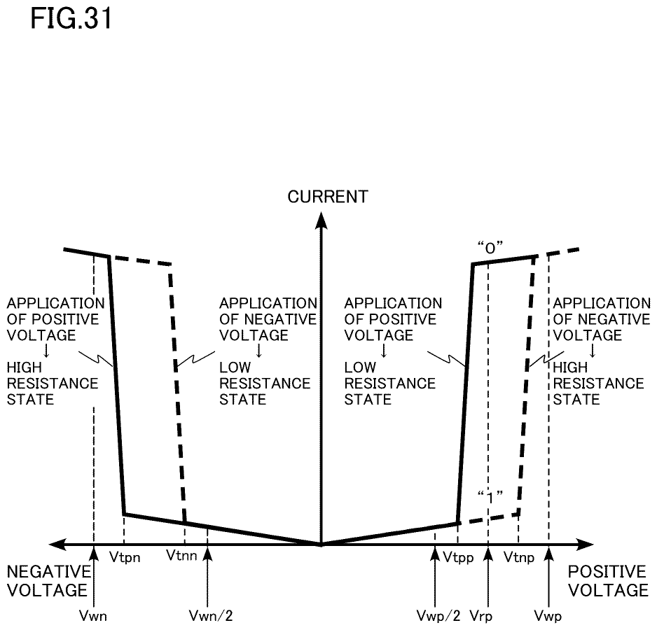

FIG. 31 is an explanatory diagram of a sixth operation example of the memory operation of the memory device according to the second modification example of the fifth embodiment. FIG. 31 shows a positive side write voltage Vwp, half (Vwp/2) the positive side write voltage Vwp, a negative side write voltage Vwn, half (Vwn/2) the negative side write voltage Vwn, and a positive side read voltage Vrp when performing a memory operation.

In the sixth operation example, the high resistance state and the low resistance state on the positive voltage side are used for the memory operation. In the sixth operation example, the positive side read voltage Vrp is used as a read voltage.

When writing data “1” to the selected cell, the negative side write voltage Vwn is applied to the upper electrode 20. The negative side write voltage Vwn is a voltage lower than the first negative voltage side threshold voltage Vtpn. By applying the negative side write voltage Vwn to the upper electrode 20, a high resistance state is realized on the positive voltage side, and data “1” is written to the selected cell.

When writing data “0” to the selected cell, the positive side write voltage Vwp is applied to the upper electrode 20. The positive side write voltage Vwp is a voltage higher than the second positive voltage side threshold voltage Vtnp. By applying the positive side write voltage Vwp to the upper electrode 20, a low resistance state is realized on the positive voltage side, and data “0” is written to the selected cell.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the first positive voltage side threshold voltage Vtpp. In addition, the voltage Vwn/2 is higher than the second negative voltage side threshold voltage Vtnn.

Therefore, even when the half-selected cell is in the low resistance state, the half-select leakage current flowing through the half-selected cell can be suppressed. As a result, the memory element also functions as a switching element.

When reading data from the selected cell, the positive side read voltage Vrp is applied to the selected cell. The data of the selected cell can be determined by detecting a current change or an electric potential change caused by the difference between a current that flows when data is “1” and a current that flows when data is “0”.

In addition, in the case of the sixth operation example, regardless of whether the data of the selected cell is data “1” or data “0”, the application of the positive side read voltage Vrp does not destroy the data. In other words, in the case of the sixth operation example, non-destructive reading is possible regardless of whether the data of the selected cell is data “1” or data “0”.

### Third Modification Example

A memory device according to a third modification example of the fifth embodiment is different from the memory device according to the fifth embodiment in that the current-voltage characteristics of the memory elements are different.

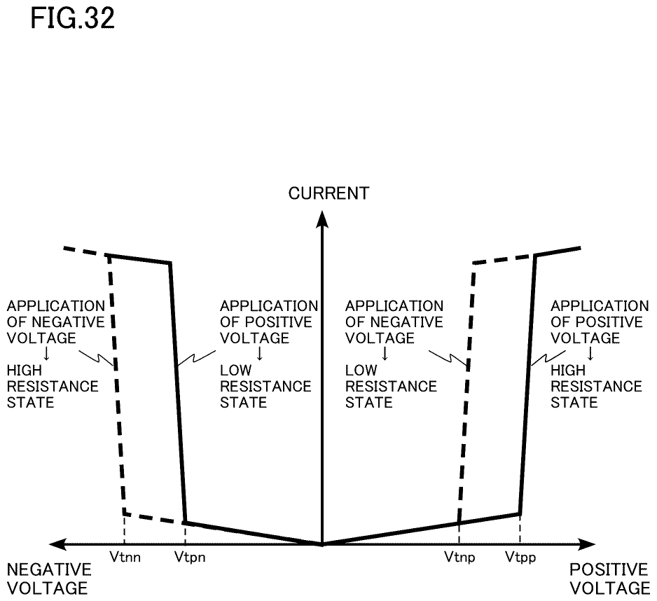

FIG. 32 is an explanatory diagram of the current-voltage characteristics of a memory element in the third modification example of the fifth embodiment. The horizontal axis indicates a voltage applied to the memory element, and the vertical axis indicates a current flowing through the memory element. In FIG. 32, the horizontal axis indicates a voltage applied to the upper electrode 20 with the electric potential of the lower electrode 10 as a reference. FIG. 32 shows the current-voltage characteristics of the memory layer 60 in the third modification example of the fifth embodiment. FIG. 32 shows the current-voltage characteristics of the memory cell MC in the third modification example of the fifth embodiment.

The memory element in the third modification example of the fifth embodiment shows different current-voltage characteristics when a predetermined positive voltage is applied to the upper electrode 20 and when a predetermined negative voltage is applied to the upper electrode 20. In FIG. 32, the solid line indicates the current-voltage characteristics when a predetermined positive voltage is applied to the upper electrode 20, and the dotted line indicates the current-voltage characteristics when a predetermined negative voltage is applied to the upper electrode 20.

When a predetermined positive voltage is applied to the upper electrode 20, the current increases abruptly at a first positive voltage side threshold voltage Vtpp on the positive voltage side. In addition, when a predetermined positive voltage is applied to the upper electrode 20, the current increases abruptly at a first negative voltage side threshold voltage Vtpn on the negative voltage side.

On the other hand, when a predetermined negative voltage is applied to the upper electrode 20, the current increases abruptly at a second positive voltage side threshold voltage Vtnp on the positive voltage side. In addition, when a predetermined negative voltage is applied to the upper electrode 20, the current increases abruptly at a second negative voltage side threshold voltage Vtnn on the negative voltage side.

The first positive voltage side threshold voltage Vtpp is higher than the second positive voltage side threshold voltage Vtnp. In addition, the first negative voltage side threshold voltage Vtpn is higher than the second negative voltage side threshold voltage Vtnn.

The memory element according to the third modification example of the fifth embodiment can have a high resistance state and a low resistance state on both the positive voltage side and the negative voltage side. When a predetermined positive voltage is applied to the upper electrode 20, a high resistance state is realized on the positive voltage side and a low resistance state is realized on the negative voltage side. On the other hand, when a predetermined negative voltage is applied to the upper electrode 20, a low resistance state is realized on the positive voltage side and a high resistance state is realized on the negative voltage side. Hereinafter, the high resistance state will be defined as data “1”, and the low resistance state will be defined as data “0”. The memory cell MC can store 1-bit data of “0” and “1”.

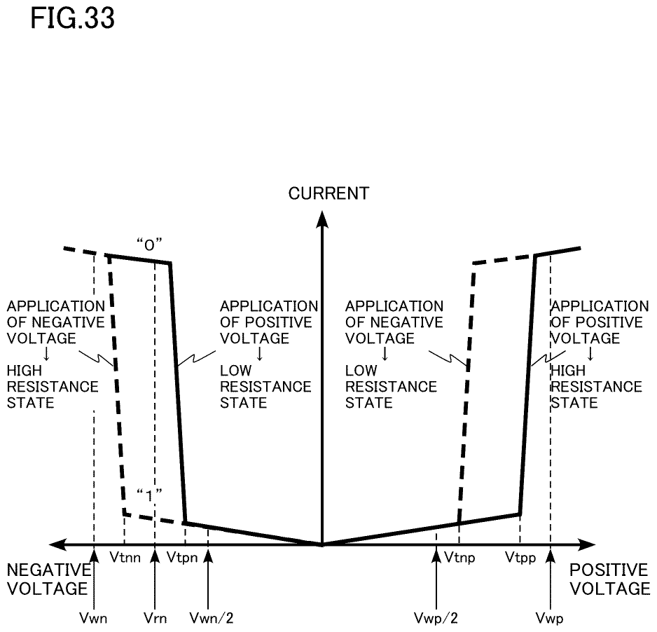

FIG. 33 is an explanatory diagram of a seventh operation example of the memory operation of the memory device according to the third modification example of the fifth embodiment. FIG. 33 shows a positive side write voltage Vwp, half (Vwp/2) the positive side write voltage Vwp, a negative side write voltage Vwn, half (Vwn/2) the negative side write voltage Vwn, and a negative side read voltage Vrn when performing a memory operation.

In the seventh operation example, the high resistance state and the low resistance state on the negative voltage side are used for the memory operation. In the seventh operation example, the negative side read voltage Vrn is used as a read voltage.

When writing data “1” to the selected cell, the negative side write voltage Vwn is applied to the upper electrode 20. The negative side write voltage Vwn is a voltage lower than the second negative voltage side threshold voltage Vtnn. By applying the negative side write voltage Vwn to the upper electrode 20, a high resistance state is realized on the negative voltage side, and data “1” is written to the selected cell.

When writing data “0” to the selected cell, the positive side write voltage Vwp is applied to the upper electrode 20. The positive side write voltage Vwp is a voltage higher than the first positive voltage side threshold voltage Vtpp. By applying the positive side write voltage Vwp to the upper electrode 20, a low resistance state is realized on the negative voltage side, and data “0” is written to the selected cell.

In the seventh operation example, when writing data “1” to the selected cell, assuming that the data stored in the selected cell is data “0”, a current flows if the negative side write voltage Vwn is lower than the first negative voltage side threshold voltage Vtpn even if the negative side write voltage Vwn is higher than the second negative voltage side threshold voltage Vtnn. For this reason, data “1” may be written. Therefore, for example, by setting the negative side write voltage Vwn to a voltage between the second negative voltage side threshold voltage Vtnn and the first negative voltage side threshold voltage Vtpn, it is possible to reduce the power consumption of the memory device or increase the reliability.

In addition, in the seventh operation example, when writing data “0” to the selected cell, assuming that the data stored in the selected cell is data “1”, a current flows if the positive side write voltage Vwp is higher than the second positive voltage side threshold voltage Vtnp even if the positive side write voltage Vwp is lower than the first positive voltage side threshold voltage Vtpp. For this reason, data “0” may be written. Therefore, for example, by setting the positive side write voltage Vwp to a voltage between the second positive voltage side threshold voltage Vtnp and the first positive voltage side threshold voltage Vtpp, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the second positive voltage side threshold voltage Vtnp. In addition, the voltage Vwn/2 is higher than the first negative voltage side threshold voltage Vtpn.

Therefore, even when the half-selected cell is in the low resistance state, the half-select leakage current flowing through the half-selected cell can be suppressed. As a result, the memory element also functions as a switching element.

When reading data from the selected cell, the negative side read voltage Vrn is applied to the selected cell. The data of the selected cell can be determined by detecting a current change or an electric potential change caused by the difference between a current that flows when data is “1” and a current that flows when data is “0”.

In addition, in the case of the seventh operation example, when the data of the selected cell is data “1”, the application of the negative side read voltage Vrn does not destroy the data. In other words, in the case of the seventh operation example, non-destructive reading is possible if the data of the selected cell is data “1”.

On the other hand, when the data of the selected cell is data “0”, the application of the negative side read voltage Vrn lower than the first negative voltage side threshold voltage Vtpn may cause a current to flow. As a result, the data of the selected cell may change to data “1”. In other words, in the case of the seventh operation example, when the data of the selected cell is data “0”, there is a possibility of destructive reading. Therefore, when the data of the selected cell is data “0”, it may be necessary to rewrite the data “0” in order to maintain the data of the selected cell after reading the data of the selected cell.

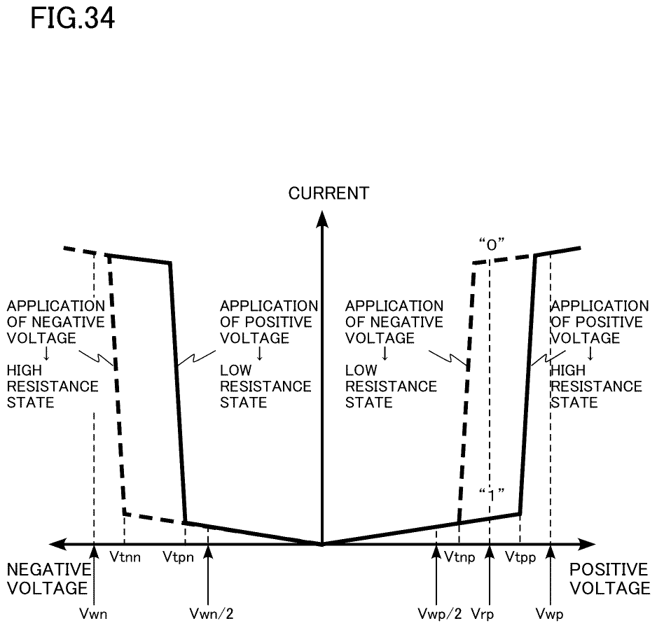

FIG. 34 is an explanatory diagram of an eighth operation example of the memory operation of the memory device according to the third modification example of the fifth embodiment. FIG. 34 shows a positive side write voltage Vwp, half (Vwp/2) the positive side write voltage Vwp, a negative side write voltage Vwn, half (Vwn/2) the negative side write voltage Vwn, and a positive side read voltage Vrp when performing a memory operation.

In the eighth operation example, the high resistance state and the low resistance state on the positive voltage side are used for the memory operation. In the eighth operation example, the positive side read voltage Vrp is used as a read voltage.

When writing data “1” to the selected cell, the positive side write voltage Vwp is applied to the upper electrode 20. The positive side write voltage Vwp is a voltage higher than the first positive voltage side threshold voltage Vtpp. By applying the positive side write voltage Vwp to the upper electrode 20, a high resistance state is realized on the positive voltage side, and data “1” is written to the selected cell.

When writing data “0” to the selected cell, the negative side write voltage Vwn is applied to the upper electrode 20. The negative side write voltage Vwn is a voltage lower than the second negative voltage side threshold voltage Vtnn. By applying the negative side write voltage Vwn to the upper electrode 20, a low resistance state is realized on the positive voltage side, and data “0” is written to the selected cell.

In the eighth operation example, when writing data “1” to the selected cell, assuming that the data stored in the selected cell is data “0”, a current flows if the positive side write voltage Vwp is higher than the second positive voltage side threshold voltage Vtnp even if the positive side write voltage Vwp is lower than the first positive voltage side threshold voltage Vtpp. For this reason, data “1” may be written. Therefore, for example, by setting the positive side write voltage Vwp to a voltage between the second positive voltage side threshold voltage Vtnp and the first positive voltage side threshold voltage Vtpp, it is possible to reduce the power consumption of the memory device or increase the reliability.

In addition, in the eighth operation example, when writing data “0” to the selected cell, assuming that the data stored in the selected cell is data “1”, a current flows if the negative side write voltage Vwn is lower than the first negative voltage side threshold voltage Vtpn even if the negative side write voltage Vwn is higher than the second negative voltage side threshold voltage Vtnn. For this reason, data “0” may be written. Therefore, for example, by setting the negative side write voltage Vwn to a voltage between the second negative voltage side threshold voltage Vtnn and the first negative voltage side threshold voltage Vtpn, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the second positive voltage side threshold voltage Vtnp. In addition, the voltage Vwn/2 is higher than the first negative voltage side threshold voltage Vtpn.

Therefore, even when the half-selected cell is in the low resistance state, the half-select leakage current flowing through the half-selected cell can be suppressed. As a result, the memory element also functions as a switching element.

When reading data from the selected cell, the positive side read voltage Vrp is applied to the selected cell. The data of the selected cell can be determined by detecting a current change or an electric potential change caused by the difference between a current that flows when data is “1” and a current that flows when data is “0”.

In addition, in the case of the eighth operation example, when the data of the selected cell is data “1”, the application of the positive side read voltage Vrp does not destroy the data. In other words, in the case of the eighth operation example, non-destructive reading is possible if the data of the selected cell is data “1”.

On the other hand, when the data of the selected cell is data “0”, the application of the positive side read voltage Vrp higher than the second positive voltage side threshold voltage Vtnp may cause a current to flow. As a result, the data of the selected cell may change to data “1”. In other words, in the case of the eighth operation example, when the data of the selected cell is data “0”, there is a possibility of destructive reading. Therefore, when the data of the selected cell is data “0”, it may be necessary to rewrite the data “0” in order to maintain the data of the selected cell after reading the data of the selected cell.

In the memory devices according to the fifth embodiment and its modification examples, the memory element of the memory cell MC has a switching function and an information storage function. The memory layer 60 is a single layer, and realizes the function of the switching layer 40 and the function of the variable resistance layer 50 in the first and second embodiments. Since the memory layer 60 in the fifth embodiment is a single layer and has a switching function and a memory function, the structure of the memory cell MC can be made very simple.

In addition, the memory layer 60 of the memory device according to the fifth embodiment and its modification examples has the same configuration as the switching layer 40 in the first embodiment. Therefore, according to the fifth embodiment and its modification examples, it is possible to realize a memory device having excellent switching characteristics as in the first embodiment.

In addition, the plurality of current-voltage characteristics of the memory elements shown in the fifth embodiment and its modification examples can be realized, for example, by adopting the memory layer 60 having an appropriate chemical composition.

Although the magnetoresistive memory has been described as an example of the two-terminal memory device in the first to third embodiments and the resistive random access memory has been described as an example of the memory device in the fourth embodiment, embodiments can be applied to other two-terminal memory devices. For example, embodiments can be applied to a phase change memory (PCM) or a ferroelectric random access memory (FeRAM).

Although the case where the switching layer in the first embodiment is applied as a switching layer of a resistive random access memory has been described as an example in the fourth embodiment, the switching layer in the modification example of the first embodiment, the second embodiment or its modification examples, or the third embodiment or its modification examples can also be applied as the switching layer.

Although the case where the switching layer in the first embodiment is applied to the memory layer has been described as an example in the fifth embodiment, the switching layer in the modification example of the first embodiment, the second embodiment or its modification examples, or the third embodiment or its modification examples can also be applied to the memory layer.

While certain embodiments have been described, these embodiments have been presented by way of example only, and are not intended to limit the scope of the inventions. Indeed, the memory device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A memory device, comprising:
a memory cell including a first conductive layer, a second conductive layer, a third conductive layer provided between the first conductive layer and the second conductive layer, a switching layer provided between the first conductive layer and the third conductive layer, and a variable resistance layer provided between the third conductive layer and the second conductive layer,
wherein the switching layer contains:
an oxide, a nitride, or an oxynitride of a first element being at least one element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg);
a second element being different from the first element, and being at least one element selected from a group consisting of aluminum (Al), zinc (Zn), tin (Sn), gallium (Ga), and indium (In); and
a third element being at least one element selected from a group consisting of tellurium (Te), sulfur(S), selenium (Se), and antimony (Sb),
wherein the switching layer includes a first region and a second region, and the second region is provided either between the first region and the first conductive layer or between the first region and the third conductive layer, and
assuming that a sum of an atomic concentration of the first element, an atomic concentration of the second element, an atomic concentration of the third element, an atomic concentration of oxygen (O), and an atomic concentration of nitrogen (N) is a summed concentration,
a first concentration obtained by dividing a sum of an atomic concentration of the second element and an atomic concentration of the third element in the first region by the summed concentration is higher than a second concentration obtained by dividing a sum of an atomic concentration of the second element and an atomic concentration of the third element in the second region by the summed concentration.

2. The memory device according to claim 1,
wherein a thickness of the switching layer in a first direction from the first conductive layer to the second conductive layer is equal to or more than 4 nm and equal to or less than 25 nm.

3. The memory device according to claim 1,
wherein a first portion of the first region is in contact with one of the first conductive layer and the third conductive layer, and a second portion of the second region is in contact with the other of the first conductive layer and the third conductive layer, and
a difference between the first concentration of the first portion and the second concentration of the second portion is equal to or more than 10%.

4. The memory device according to claim 3,
wherein the first concentration of the first portion is equal to or less than 99%, and the second concentration of the second portion is equal to or more than 30%.

5. The memory device according to claim 1,
wherein a first portion of the first region is in contact with one of the first conductive layer and the third conductive layer, and a second portion of the second region is in contact with the other of the first conductive layer and the third conductive layer, and
the first concentration of the first portion is equal to or more than 20%, and the second concentration of the second portion is less than 30%.

6. The memory device according to claim 5,
wherein a difference between the first concentration of the first portion and the second concentration of the second portion is equal to or more than 20%.

7. The memory device according to claim 5,
wherein, in a distribution of a concentration obtained by dividing a sum of an atomic concentration of the second element and an atomic concentration of the third element by the summed concentration, in a first direction from the first conductive layer to the second conductive layer, in the switching layer,
when the second region is in contact with the first conductive layer, a distance in the first direction from the first conductive layer to a first position where the concentration is 30% is equal to or more than 0.1 nm and equal to or less than 4 nm, and a distance from the third conductive layer to the first position in the first direction is equal to or more than 4 nm, and
when the second region is in contact with the third conductive layer, a distance in the first direction from the third conductive layer to a second position where the concentration is 30% is equal to or more than 0.1 nm and equal to or less than 4 nm, and a distance from the first conductive layer to the second position in the first direction is equal to or more than 4 nm.

8. The memory device according to claim 1,
wherein the switching layer further includes a third region, and the first region is provided between the third region and the second region, and
a third concentration obtained by dividing a sum of an atomic concentration of the second element and an atomic concentration of the third element in the third region by the summed concentration is lower than the second concentration.

9. The memory device according to claim 8,
wherein, in a distribution of a concentration obtained by dividing a sum of an atomic concentration of the second element and an atomic concentration of the third element by the summed concentration, in a first direction from the first conductive layer to the second conductive layer, in the switching layer,
when the third region is in contact with the first conductive layer, a distance in the first direction from the first conductive layer to a position where the distribution has a maximum value is smaller than a distance from the third conductive layer to the position in the first direction, and
when the third region is in contact with the third conductive layer, a distance from the third conductive layer to the position in the first direction is smaller than a distance from the first conductive layer to the position in the first direction.

10. The memory device according to claim 8,
wherein a third portion of the third region is in contact with one of the first conductive layer and the third conductive layer, and
the third concentration of the third portion is less than 30%.

11. The memory device according to claim 10,
wherein a fourth portion of the second region is in contact with the other of the first conductive layer and the third conductive layer, and
in a distribution of a concentration obtained by dividing a sum of an atomic concentration of the second element and an atomic concentration of the third element by the summed concentration, in a first direction from the first conductive layer to the second conductive layer, in the switching layer,
a difference between the concentration at a position where the distribution has a maximum value and the second concentration of the fourth portion is equal to or more than 10%.

12. The memory device according to claim 9,
wherein, when the third region is in contact with the first conductive layer, a distance in the first direction from the first conductive layer to a third position where the concentration in the distribution is 30% is equal to or more than 0.1 nm and equal to or less than 4 nm, and a distance from the third conductive layer to the third position in the first direction is equal to or more than 4 nm, and
when the third region is in contact with the third conductive layer, a distance in the first direction from the third conductive layer to a fourth position where the concentration in the distribution is 30% is equal to or more than 0.1 nm and equal to or less than 4 nm, and a distance from the first conductive layer to the fourth position in the first direction is equal to or more than 4 nm.

13. The memory device according to claim 1,
wherein the switching layer contains a compound of the second element and the third element.

14. The memory device according to claim 1,
wherein a concentration obtained by dividing a sum of an atomic concentration of the second element and an atomic concentration of the third element by the summed concentration monotonically increases or decreases from the first conductive layer to the third conductive layer.

15. The memory device according to claim 1,
wherein the first conductive layer, the second conductive layer, or the third conductive layer contains at least one material selected from a group consisting of carbon, carbon nitride, tungsten, tungsten carbide, tungsten nitride, titanium, titanium nitride, tantalum, tantalum carbide, and tantalum nitride.

16. The memory device according to claim 1,
wherein the first conductive layer, the second conductive layer, or the third conductive layer contains at least one material selected from a group consisting of hafnium, hafnium boride, magnesium aluminum boride, zirconium, zirconium boride, and titanium boride.

17. The memory device according to claim 1,
wherein the variable resistance layer includes a magnetic tunnel junction.

18. The memory device according to claim 1,
wherein the variable resistance layer has an electrical resistance changing by application of a predetermined voltage, and
the switching layer has a nonlinear current-voltage characteristic that a current increases at a specific threshold voltage.

19. The memory device according to claim 1, further comprising:
a plurality of first wirings; and
a plurality of second wirings crossing the plurality of first wirings,
wherein the memory cell is provided in a region where one of the plurality of first wirings and one of the plurality of second wirings cross each other.

20. A memory device, comprising:
a memory cell including a first conductive layer, a second conductive layer, and a memory layer provided between the first conductive layer and the second conductive layer,
wherein the memory layer contains:
an oxide, a nitride, or an oxynitride of a first element being at least one element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg);
a second element being different from the first element, and being at least one element selected from a group consisting of aluminum (Al), zinc (Zn), tin (Sn), gallium (Ga), and indium (In); and
a third element being at least one element selected from a group consisting of tellurium (Te), sulfur(S), selenium (Se), and antimony (Sb),
wherein the memory layer includes a first region and a second region, and the second region is provided either between the first region and the first conductive layer or between the first region and the second conductive layer, and
assuming that a sum of an atomic concentration of the first element, an atomic concentration of the second element, an atomic concentration of the third element, an atomic concentration of oxygen (O), and an atomic concentration of nitrogen (N) is a summed concentration,
a first concentration obtained by dividing a sum of an atomic concentration of the second element and an atomic concentration of the third element in the first region by the summed concentration is higher than a second concentration obtained by dividing a sum of an atomic concentration of the second element and an atomic concentration of the third element in the second region by the summed concentration.

21. The memory device according to claim 20,
wherein a thickness of the memory layer in a first direction from the first conductive layer to the second conductive layer is equal to or more than 4 nm and equal to or less than 25 nm.

22. The memory device according to claim 20,
wherein a first portion of the first region is in contact with one of the first conductive layer and the second conductive layer, and a second portion of the second region is in contact with the other of the first conductive layer and the second conductive layer, and
a difference between the first concentration of the first portion and the second concentration of the second portion is equal to or more than 10%.

23. The memory device according to claim 22,
wherein the first concentration of the first portion is equal to or less than 99%, and the second concentration of the second portion is equal to or more than 30%.

24. The memory device according to claim 20,
wherein a first portion of the first region is in contact with one of the first conductive layer and the second conductive layer, and a second portion of the second region is in contact with the other of the first conductive layer and the second conductive layer, and
the first concentration of the first portion is equal to or more than 20%, and the second concentration of the second portion is less than 30%.

25. The memory device according to claim 24,
wherein a difference between the first concentration of the first portion and the second concentration of the second portion is equal to or more than 20%.

26. The memory device according to claim 24,
wherein, in a distribution of a concentration obtained by dividing a sum of an atomic concentration of the second element and an atomic concentration of the third element by the summed concentration, in a first direction from the first conductive layer to the second conductive layer, in the memory layer,
when the second region is in contact with the first conductive layer, a distance in the first direction from the first conductive layer to a first position where the concentration is 30% is equal to or more than 0.1 nm and equal to or less than 4 nm, and a distance from the second conductive layer to the first position in the first direction is equal to or more than 4 nm, and
when the second region is in contact with the second conductive layer, a distance in the first direction from the second conductive layer to a second position where the concentration is 30% is equal to or more than 0.1 nm and equal to or less than 4 nm, and a distance from the first conductive layer to the second position in the first direction is equal to or more than 4 nm.

27. The memory device according to claim 20,
wherein the memory layer further includes a third region, and the first region is provided between the third region and the second region, and
a third concentration obtained by dividing a sum of an atomic concentration of the second element and an atomic concentration of the third element in the third region by the summed concentration is lower than the second concentration.

28. The memory device according to claim 27,
wherein, in a distribution of a concentration obtained by dividing a sum of an atomic concentration of the second element and an atomic concentration of the third element by the summed concentration, in a first direction from the first conductive layer to the second conductive layer, in the memory layer,
when the third region is in contact with the first conductive layer, a distance in the first direction from the first conductive layer to a position where the distribution has a maximum value is smaller than a distance from the second conductive layer to the position in the first direction, and
when the third region is in contact with the second conductive layer, a distance from the second conductive layer to the position in the first direction is smaller than a distance from the first conductive layer to the position in the first direction.

29. The memory device according to claim 27,
wherein a third portion of the third region is in contact with one of the first conductive layer and the second conductive layer, and
the third concentration of the third portion is less than 30%.

30. The memory device according to claim 29,
wherein a fourth portion of the second region is in contact with the other of the first conductive layer and the second conductive layer, and
in a distribution of a concentration obtained by dividing a sum of an atomic concentration of the second element and an atomic concentration of the third element by the summed concentration, in a first direction from the first conductive layer to the second conductive layer, in the memory layer,
a difference between the concentration at a position where the distribution has a maximum value and the second concentration of the fourth portion is equal to or more than 10%.

31. The memory device according to claim 28,
wherein, when the third region is in contact with the first conductive layer, a distance in the first direction from the first conductive layer to a third position where the concentration in the distribution is 30% is equal to or more than 0.1 nm and equal to or less than 4 nm, and a distance from the second conductive layer to the third position in the first direction is equal to or more than 4 nm, and
when the third region is in contact with the second conductive layer, a distance in the first direction from the second conductive layer to a fourth position where the concentration in the distribution is 30% is equal to or more than 0.1 nm and equal to or less than 4 nm, and a distance from the first conductive layer to the fourth position in the first direction is equal to or more than 4 nm.

32. The memory device according to claim 20,
wherein the memory layer contains a compound of the second element and the third element.

33. The memory device according to claim 20,
wherein a concentration obtained by dividing a sum of an atomic concentration of the second element and an atomic concentration of the third element by the summed concentration monotonically increases or decreases from the first conductive layer to the second conductive layer.

34. The memory device according to claim 20,
wherein the memory layer has a nonlinear current-voltage characteristic that a current increases at a specific threshold voltage, and the threshold voltage changes by application of a predetermined voltage.

35. The memory device according to claim 20, further comprising:
a plurality of first wirings; and
a plurality of second wirings crossing the plurality of first wirings,
wherein the memory cell is provided in a region where one of the plurality of first wirings and one of the plurality of second wirings cross each other.
